(19) United States
(12) Patent Application Publication
(10) Pub. No.: US 2023/0207694 A1
(43) Pub. Date: Jun. 29, 2023

(54) SEMICONDUCTOR DEVICE AND MANUFACTURING METHOD THEREOF

(71) Applicants: TAIWAN SEMICONDUCTOR MANUFACTURING COMPANY, LTD., Hsinchu (TW); TSMC China Company Limited, Shanghai (CN)

(72) Inventors: Hang FAN, Shanghai City (CN); Feng HAN, Shanghai City (CN); Zheng Long CHEN, New Taipei City (TW); Jian-Hua LU, Shanghai City (CN)

(73) Assignees: TAIWAN SEMICONDUCTOR MANUFACTURING COMPANY, LTD., Hsinchu (TW); TSMC China Company Limited, Shanghai (CN)

(21) Appl. No.: 17/694,088

(22) Filed: Mar. 14, 2022

(30) Foreign Application Priority Data
Dec. 29, 2021 (CN) 202111639302.X

(51) Int. Cl. H01L 29/78; H01L 21/8238

(52) U.S. Cl. CPC H01L 29/7835; H01L 29/7816; H01L 21/823892

(57) ABSTRACT

A semiconductor device includes a substrate, a first well region in the substrate, a gate structure over the substrate, a second well region and a third well region in the substrate and under the gate structure, and a source region and a drain region on opposite sides of the gate structure. The drain region is in the second well region and the source region is in the third well region. The drain region has a first doped region and a second doped region, and the first doped region and the second doped region have different conductivity types.

### PRIORITY CLAIM AND CROSS-REFERENCE

The present application claims priority to China Application Serial Number 202111639302.X, filed Dec. 29, 2021, which is herein incorporated by reference.

### BACKGROUND

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node (e.g., shrink the process node towards the sub-20 nm node). As semiconductor devices are scaled down, new techniques are desired to maintain the electronic components' performance from one generation to the next. For example, low on-resistance and high breakdown voltage of transistors are desirable for various high power applications.

As semiconductor technologies evolve, metal oxide semiconductor field effect transistors (MOSFET) have been widely used in today's integrated circuits. MOSFETs are voltage controlled devices. When a control voltage is applied to the gate of a MOSFET and the control voltage is greater than the threshold of the MOSFET, a conductive channel is established between the drain and the source of the MOSFET. As a result, a current flows between the drain and the source of the MOSFET. On the other hand, when the control voltage is less than the threshold of the MOSFET, the MOSFET is turned off accordingly.

According to the polarity difference, MOSFETs may include at least two categories. One is n-channel MOSFETs; the other is p-channel MOSFETs. On the other hand, according to the structure difference, MOSFETs can be further divided into three sub-categories, planar MOSFETs, lateral diffused MOS (LDMOS) FETs and vertical diffused MOSFETs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrate a block diagram of a method of forming a semiconductor device in accordance with some embodiments.

FIGS. 2 to 11 illustrate a method for manufacturing a semiconductor device in different stages in accordance with some embodiments.

FIG. 12 is a cross-sectional view of the semiconductor device in accordance with some embodiments.

FIG. 13 is a top view of a layout of the semiconductor device of FIG. 12.

FIG. 14 is an equivalent circuit model of the semiconductor device of FIG. 12.

FIG. 15 is a top view of a layout of a semiconductor device in accordance with some embodiments.

FIG. 16 is a top view of a layout of a semiconductor device in accordance with some embodiments.

FIGS. 17A and 17B illustrate a block diagram of a method of forming a semiconductor device in accordance with some embodiments.

FIGS. 18 to 22 illustrate a method for manufacturing a semiconductor device in different stages in accordance with some embodiments.

FIG. 23A and 23B illustrate a block diagram of a method of forming a semiconductor device in accordance with some embodiments.

FIGS. 24 to 30 illustrate a method for manufacturing a semiconductor device in different stages in accordance with some embodiments.

FIGS. 31A and 31B illustrate a block diagram of a method of forming a semiconductor device in accordance with some embodiments.

FIGS. 32 to 36 illustrate a method for manufacturing a semiconductor device in different stages in accordance with some embodiments.

FIG. 37 is a cross-sectional view of a semiconductor device in accordance with some embodiments.

FIG. 38 is a cross-sectional view of a semiconductor device in accordance with some embodiments.

FIG. 39 is a cross-sectional view of a semiconductor device in accordance with some embodiments.

FIG. 40 is a cross-sectional view of a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated.

The lateral diffused (LD) MOS transistor has advantages. For example, the LDMOS transistor is capable of delivering more current per unit area because its asymmetric structure provides a short channel between the drain and the source of the LDMOS transistor. The present disclosure will be described with respect to embodiments in a specific context, a lateral diffused (LD) metal oxide semiconductor field effect transistor (MOSFET) having a drain region, wherein the drain region include a first doped region and a second doped region adjacent to the first doped region to increase discharging capability. Further, lower voltage drop and lower surface electrical field can be achieved. The embodiments of the disclosure may also be applied, however, to a variety of metal oxide semiconductor transistors. Hereinafter, various embodiments will be explained in detail with reference to the accompanying drawings.

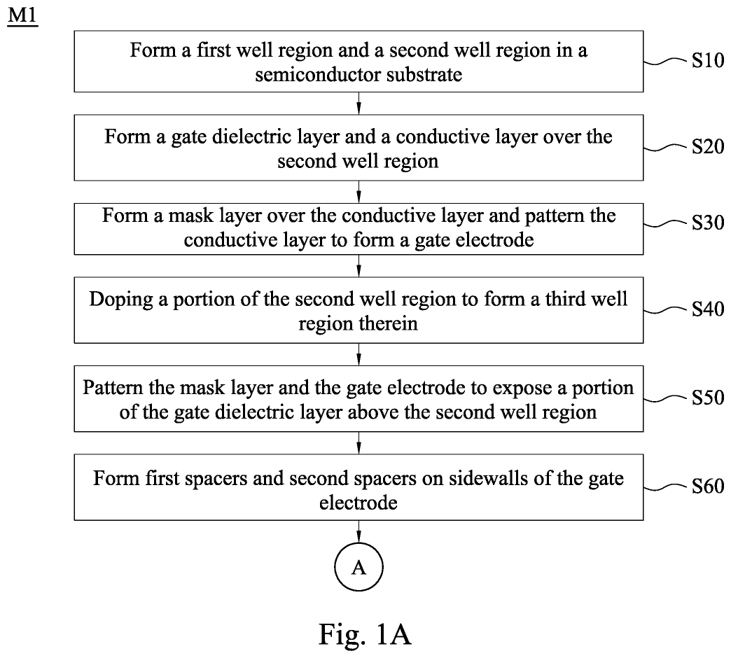

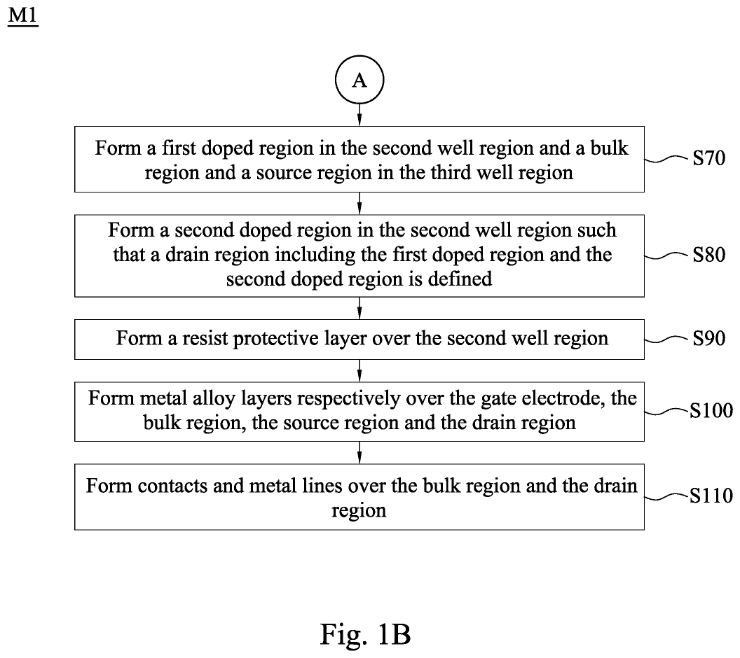

Referring now to FIGS. 1A and 1B, illustrated is an exemplary method M1 for fabrication of a semiconductor device in accordance with some embodiments. The method M1 includes a relevant part of the entire manufacturing process. It is understood that additional operations may be provided before, during, and after the operations shown by FIGS. 1A and 1B, and some of the operations described below can be replaced or eliminated for additional embodiments of the method. The order of the operations/processes may be interchangeable. The method M1 includes fabrication of a semiconductor device 100.

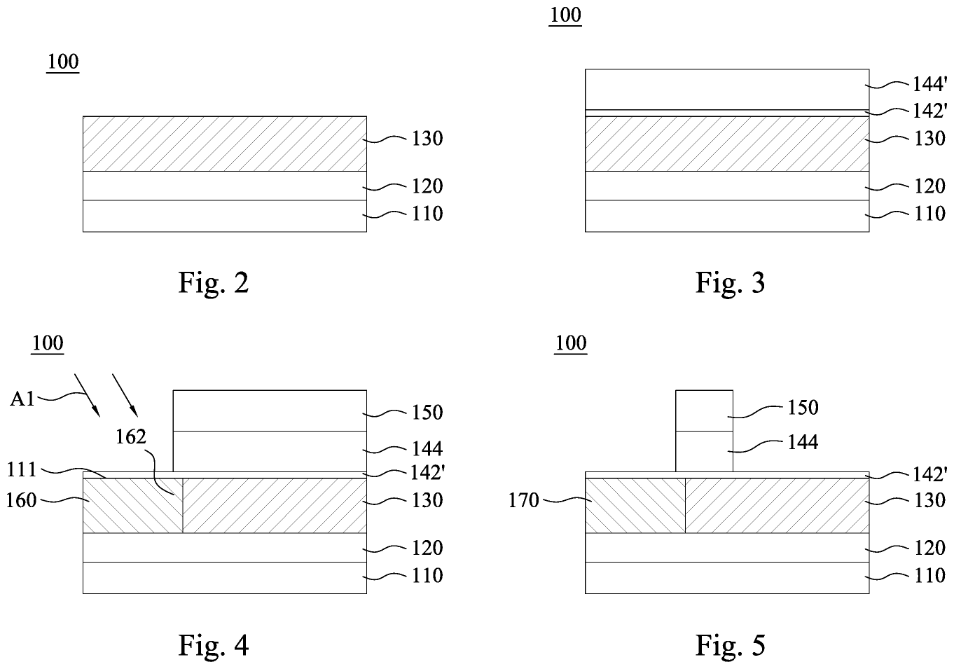

It is noted that FIGS. 1A and 1B has been simplified for a better understanding of the disclosed embodiment. Moreover, the semiconductor device 100 may be configured as a system-on-chip (SoC) device having various PMOS and NMOS transistors that are fabricated to operate at different voltage levels. The PMOS and NMOS transistors may provide low voltage functionality including logic/memory devices and input/output devices, and high voltage functionality including power management devices. It is understood that the semiconductor device 100 in FIGS. 2-12 may also include resistors, capacitors, inductors, diodes, and other suitable microelectronic devices that may be implemented in integrated circuits.

FIGS. 2 to 11 illustrate a method for manufacturing the semiconductor device 100 in different stages in accordance with some embodiments. The method M1 begins at block S10 where a first well region and a second well region are formed in a semiconductor substrate. With reference to FIG. 2, in some embodiments of block S10, a first well region 120 and a second well region 130 are formed in the semiconductor substrate 110. The semiconductor substrate 110 may include a semiconductor wafer such as a silicon wafer. Alternatively, the semiconductor substrate 110 may include other elementary semiconductors such as germanium. The semiconductor substrate 110 may also include a compound semiconductor such as silicon carbide, gallium arsenic, indium arsenide, indium phosphide, or other suitable materials. Moreover, the semiconductor substrate 110 may include an alloy semiconductor such as silicon germanium, silicon germanium carbide, gallium arsenic phosphide, and gallium indium phosphide, or other suitable materials. In some embodiments, the semiconductor substrate 110 includes an epitaxial layer (epi layer) overlying a bulk semiconductor. Furthermore, the semiconductor substrate 110 may include a semiconductor-on-insulator (SOI) structure. For example, the semiconductor substrate 110 may include a buried oxide (BOX) layer formed by a process such as separation by implanted oxygen (SIMOX). In various embodiments, the semiconductor substrate 110 may include a buried layer such as an N-type buried layer (NBL), a P-type buried layer (PBL), and/or a buried dielectric layer including a buried oxide (BOX) layer. In the some embodiments, illustrated as an N-type MOS, the semiconductor substrate 110 includes a P-type silicon substrate (p-substrate). For example, P-type impurities (e.g., boron) are doped into the semiconductor substrate 110 to form the p-substrate. To form a complementary MOS, an N-type buried layer, i.e., deep n-well (DNW), may be implanted deeply under an active region of the P-type MOS of the p-substrate (e.g., semiconductor substrate 110) as described below.

In FIG. 2, the first well region 120 is formed in the semiconductor substrate 110. The first well region 120 may be formed by doping the semiconductor substrate 110 with first dopants having first conductivity type (e.g., P-type in this case) such as boron (B), BF₂, BF₃, combinations thereof, or the like. For example, an implantation process is performed on the semiconductor substrate 110 to form the first well region 120, followed by an annealing process to activate the implanted first dopants of the first well region 120. In some embodiments, the first well region 120 is referred as a deep P-type well (DPW). In some embodiments, a dopant concentration of the first well region 120 is in a range of about 10¹⁶ atoms/cm³ and about 10¹⁹ atoms/cm³.

Then, the second well region 130 is formed in the semiconductor substrate 110. Specifically, the second well region 130 is formed in the first well region 120. In some embodiments, the second well region 130 is formed by ion-implantation, diffusion techniques, or other suitable techniques. The second well region 130 may be formed by doping the first well region 120 with second dopants having second conductivity type (e.g., N-type in this case) such as phosphorous (P), arsenic (As), antimony (Sb), combinations thereof, or the like. For example, an implantation process is performed on the first well region 120 to form the second well region 130, followed by an annealing process to activate the implanted second dopants of the second well region 130. In some embodiments, the second well region 130 is referred as an N-type doped region (NDD) (or N-type drift region). In some embodiments, the second dopants of the second well region 130 have different conductivity type from the first dopants of the first well region 120. The dopant concentration of the second well region 130 may be greater than the dopant concentration of the first well region 120.

Returning to FIG. 1A, the method Ml then proceeds to block S20 where a gate dielectric layer and a conductive layer are formed over the semiconductor substrate. With reference to FIG. 3, in some embodiments of block S20, a gate dielectric layer 142′ and a conductive layer 144′ are formed over the semiconductor substrate 110. The gate dielectric layer 142′ may include a silicon oxide layer. Alternatively, the gate dielectric layer 142′ may include a high-k dielectric material. The high-k material may be selected from metal oxides, metal nitrides, metal silicates, transition metal-oxides, transition metal-nitrides, transition metal-silicates, oxy-nitrides of metals, metal aluminates, zirconium silicate, zirconium aluminate, hafnium oxide, other suitable materials or combinations thereof. Alternatively, the gate dielectric layer 142′ may include oxide and/or nitride material. For example, the gate dielectric layer 142′ includes silicon oxide, silicon nitride, silicon oxynitride, SiCN, SiCₓO_{y}N_{z}, other suitable materials, or combinations thereof. In some embodiments, the gate dielectric layer 142′ may have a multilayer structure such as one layer of silicon oxide and another layer of high-k material. The gate dielectric layer 142′ may be formed using chemical vapor deposition (CVD), physical vapor deposition (PVD), atomic layer deposition (ALD), thermal oxide, other suitable processes, or combinations thereof.

Then, the conductive layer 144′ is formed over the gate dielectric layer 142′. The conductive layer 144′ may include polycrystalline silicon (interchangeably referred to as polysilicon). Alternatively, the conductive layer 144′ may include a metal such as Al, Cu, W, Ti, Ta, TiN, TaN, NiSi, CoSi, other suitable conductive materials, or combinations thereof. The conductive layer 144′ may be formed by CVD, PVD, plating, and other proper processes. The conductive layer 144′ may have a multilayer structure and may be formed in a multi-step process using a combination of different processes.

Returning to FIG. 1A, the method M1 then proceeds to block S30 where a mask layer is formed over the conductive layer and the conductive layer is patterned to form a gate electrode. With reference to FIG. 4, in some embodiments of block S30, a mask layer 150 is formed over the conductive layer 144′ in FIG. 3. The mask layer 150 may be formed by a series of operations including deposition, photolithography patterning, and etching processes. The photolithography patterning processes may include photoresist coating (e.g., spin-on coating), soft baking, mask aligning, exposure, post-exposure baking, developing the photoresist, rinsing, drying (e.g., hard baking), and/or other applicable processes. The etching processes may include dry etching, wet etching, and/or other etching methods (e.g., reactive ion etching). Then, one or more etching processes are performed to pattern the conductive layer 144′ in FIG. 3 to form a gate electrode 144 on the gate dielectric layer 142′ using the mask layer 150 as an etching mask, and the gate dielectric layer 142′ is exposed.

Returning to FIG. 1A, the method M1 then proceeds to block S40 where a portion of the second well region is doped to form a third well region therein. With reference to FIG. 4, in some embodiments of block S40, a third well region 160 is formed in the second well region 130 and in the vicinity of a top surface 111 of the semiconductor substrate 110. In some embodiments, the third well region 160 is doped with first dopants having first conductivity type (e.g., P-type in this case) such as boron (B), BF₂, BF₃, combinations thereof, or the like. The first dopants of the third well region 160 may have the same conductivity type as the first dopants of the first well region 120.

In some embodiments, the third well region 160 is formed by ion-implantation, diffusion techniques, or other suitable techniques. For example, an ion implantation utilizing P-type dopants may be performed to form the third well region 160 in the second well region 130 through the gate dielectric layer 142′ using the mask layer 150 and the gate electrode 144 as an implant mask. In FIG. 4, the third well region 160 has a portion 162 overlapping with the gate electrode 144 because of the implantation tilt angle of the ion-implantation for forming the third well region 160. For example, an implantation process is performed to implant a P-type dopant at a tilt angle (as indicated by the arrows A1) using the mask layer 150 and the gate electrode 144 as an implant mask, thus forming the third well region 160 and extending to directly below the gate electrode 144 due to the tilt angle. In some embodiments, a depth of the third well region 160 is substantially the same as a depth of the second well region 130. In some embodiments, the third well region 160 is referred as a p-body region.

Returning to FIG. 1A, the method M1 then proceeds to block S50 where the mask layer and the gate electrode are patterned to expose portions of the second well region and the third well region. With reference to FIG. 5, in some embodiments of block S50, the mask layer 150 and the gate electrode 144 are patterned to expose a portion of the gate dielectric layer 142′ above the second well region 130 by performing an etching process. In some embodiments, an exposed portion of the gate dielectric layer 142′ (i.e., the portion not covered by the gate electrode 144 and the mask layer 150) is thinned due to the etching process. In other words, a thickness of a portion of the gate dielectric layer 142′ directly below the gate electrode 144 is greater than a thickness of the exposed portion of the gate dielectric layer 142′. Thereafter, the mask layer 150 is removed after the patterning of the gate structure 140. For example, the mask layer 150 is stripped by ashing if it is a photoresist.

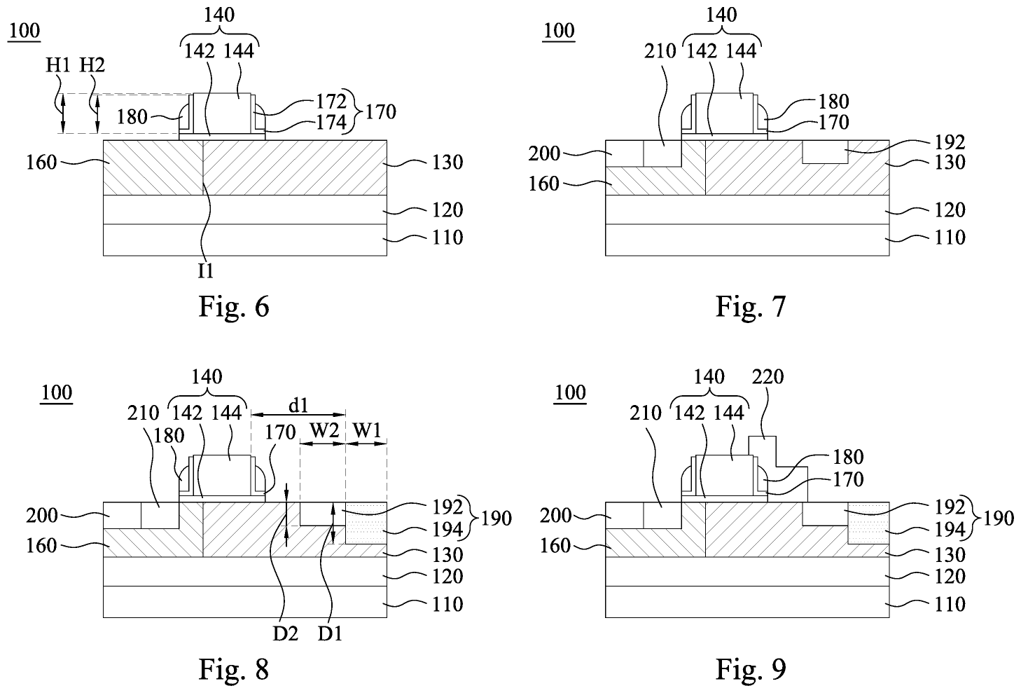

Returning to FIG. 1A, the method M1 then proceeds to block S60 where first spacers and second spacers are formed on sidewalls of the gate electrode. With reference to FIG. 6, in some embodiments of block S60, first spacers 170 are formed on sidewalls of the gate electrode 144 and then second spacers 180 are formed on the first spacer 170. In some embodiments, a first spacer layer is blanket deposited over the gate dielectric layer 142′ and the gate electrode 144. A second spacer layer is then formed over the first spacer layer. An etching process (e.g., anisotropic etching process) may be performed to etch the gate dielectric layer 142′, the first spacer layer and the second spacer layer to respectively form the gate dielectric layer 142, the first spacers 170 and the second spacers 180. The gate dielectric layer 142 and the gate electrode 144 in combination serve as a gate structure 140. In some embodiments, the gate structure 140 is formed directly above an interface I1 of the second well region 130 and the third well region 160 such that the interface I1 of the second well region 130 and the third well region 160 extends downward from the gate structure 140. In some embodiments, a bottom surface of the first spacers 170 is lower than a top surface of the gate dielectric layer 142 direct below the gate electrode 144. The first spacers 170 and the second spacers 180 in combination serve as a spacer structure. In some embodiments, the spacer structure further includes a third spacer structure formed before the first spacers 170 such that an entirety of the spacer structure serves as an oxide-nitride-oxide (ONO) spacer structure. The third spacer structure may include the same material as that of the gate dielectric layer 142. As such, the gate dielectric layer 142 and the third spacer can be defined by a single piece of material that is continuous throughout. The first spacers 170 have a height H2 measured from a top surface of the gate dielectric layer 142, and the gate electrode 144 has a height H1 measured from the top surface of the gate dielectric layer 142. In some embodiments, the height H2 of the first spacers 170 may be lower than the height H1 of the gate electrode 144 due to the nature of the anisotropic etching process that selectively etches the material of first spacers 170 at a faster etch rate than it etches the gate electrode 144. The height H2 of the first spacers 170 depends on process conditions of the anisotropic etching process (e.g., etching time duration and/or the like). Moreover, the first spacers 170 each have a vertical portion 172 vertically extending along the vertical sidewall of the gate electrode 144 and a lateral portion 174 laterally extending from an outermost sidewall of the vertical portion 172. An edge of the lateral portion 174 of each of the first spacers 170 is aligned with an edge of the gate dielectric layer 142.

In some embodiments, each of the first spacers 170 has a top surface higher than that of the second spacers 180. In some embodiments, the first spacers 170 and the second spacers 180 have different profiles. The second spacers 180 have curved outer sidewalls covering sidewalls of the first spacers 170.

In some embodiments, the first spacers 170 include silicon oxide, silicon nitride, silicon oxynitride, SiCN, SiCₓO_{y}N_{z}, other suitable materials, or combinations thereof. For example, the first spacers 170 are a dielectric material such as silicon nitride. In some embodiments, the first spacers 170 include a material different than the gate dielectric layer 142. In some embodiments, the first spacers 170 have a multilayer structure. The first spacer 170 may be formed using a deposition method, such as plasma enhanced chemical vapor deposition (PECVD), low-pressure chemical vapor deposition (LPCVD), sub-atmospheric chemical vapor deposition (SACVD), or the like. In some embodiments, the second spacers 180 include silicon oxide, silicon nitride, silicon oxynitride, SiCN, SiCₓO_{y}N_{z}, other suitable materials, or combinations thereof. For example, the second spacers 180 are a dielectric material such as silicon nitride. In some embodiments, the second spacers 180 include a material different than the first spacers 170. For example, the first spacers 170 are formed of silicon nitride, and the second spacers 180 are formed of silicon oxide. In some embodiments, the second spacers 180 are formed using a deposition method, such as plasma enhanced chemical vapor deposition (PECVD), low-pressure chemical vapor deposition (LPCVD), sub-atmospheric chemical vapor deposition (SACVD), or the like.

Returning to FIG. 1B, the method M1 then proceeds to block S70 where a first doped region is formed in the second well region and a bulk region and a source region are formed in the third well region. With reference to FIG. 7, in some embodiments of block S70, a first implantation process is performed to dope second dopants into the second well region 130 and the third well region 160, thus forming a first doped region 192 in the second well region 130 and a source region 210 in the third well region 160, and a second implantation process is performed to dope first dopants into the third well region 160, thus forming a bulk region 200 in the third well region 160. The first implantation process is performed to dope second dopants having second conductivity type (e.g., N-type in this case) into the third well region 160 and the second well region 130 to respectively form the source region 210 in the third well region 160 and the first doped region 192 in the second well region 130. The second implantation process may be performed to dope first dopants having first conductivity type (e.g., P-type in this case) into the third well region 160 to form the bulk region 200. In some embodiments, the first implantation process is performed prior to the second implantation process. In some other embodiments, the first implantation process is performed after the second implantation process.

The source region 210 and the first doped region 192 may be N+ regions (interchangeably referred to as heavily doped N-type regions) having N-type impurity concentrations greater than that of the second well region 130 and the third well region 160. In some embodiments, the source region 210 and the first doped region 192 include N-type dopants such as P or As. The bulk region 200 may be P+ or heavily doped regions having P-type impurity concentration greater than the third well region 160. In some embodiments, the bulk region 200 includes P-type dopants such as boron or boron difluoride (BF₂).

A rapid thermal annealing (RTA) process may be performed after the implantation process to activate the implanted dopants in the bulk region 200, the source region 210 and the first doped region 192. In some embodiments, a depth of the first doped region 192 may be substantially the same as a depth of the source region 210. The depth of the first doped region 192 may be substantially the same as a depth of the bulk region 200.

Returning to FIG. 1B, the method M1 then proceeds to block S80 where a second doped region is formed in the second well region such that a drain region including the first doped region and the second doped region is defined. With reference to FIG. 8, in some embodiments of block S80, a third implantation process is performed to dope first dopants into the second well region 130, thus forming a second doped region 194 in the second well region 130. The implantation process may be performed to dope first dopants having first conductivity type (e.g., P-type in this case) into the second well region 130 to form the second doped region 194 adjacent to the first doped region 192. The first doped region 192 and the second doped region 194 in combination are defined as a drain region 190. The second doped region 194 may be P+ or heavily doped regions having P-type impurity concentration greater than the second well region 130 and the third well region 160. In some embodiments, the second doped region 194 includes P-type dopants such as boron or boron difluoride (BF₂). A rapid thermal annealing (RTA) process may be performed after the implantation process to activate the implanted dopants in the second doped region 194.

Since the drain region 190 includes the first doped region 192 and the second doped region 194 adjacent to the first doped region 192, the discharging capability can be increased. Further, lower voltage drop and lower surface electrical field can be achieved.

In some embodiments, a depth D1 of the second doped region 194 of the drain region 190 is greater than a depth D2 of the first doped region 192 of the drain region 190. In some embodiments, the depth D2 of the first doped region 192 of the drain region 190, a depth of the source region 210, and a depth of the bulk region 200 are substantially the same. In some embodiments, the depth D1 of the second doped region 194 of the drain region 190 is greater than the depth of the source region 210. The depth D1 of the second doped region 194 of the drain region 190 is in a range of about 0.01 um to about 4 um, and other depth ranges are within the scope of the disclosure.

In some embodiments, a width W1 of the second doped region 194 of the drain region 190 is in a range of about 0.01 um to about 5 um, and other width ranges are within the scope of the disclosure. In some embodiments, a ratio of the width W1 of the second doped region 194 to a width W2 of the first doped region 192 is in a range of about 0.1 to about 5. In some embodiments, a lateral distance di between the gate electrode 144 and the second doped region 194 of the drain region 190 is in a range of 0.01 um to 20 um. In some embodiments, the lateral distance d1 between the gate electrode 144 and the second doped region 194 of the drain region 190 is greater than a lateral distance between the source region 210 and the gate electrode 144, and thus the LDMOS transistor has source/drain regions 210 and 190 asymmetric with respect to the gate structure 140. Moreover, the drain region 190 has a width greater than that of the source region 210. In some embodiments, the lateral distance dl between the gate electrode 144 and the second doped region 194 of the drain region 190 is greater than a lateral distance between the first doped region 192 of the drain region 190 and the gate electrode 144.

In some embodiments, a dopant concentration of the first doped region 192 of the drain region 190 is in a range of about 10¹⁸ atoms/cm³ and about 10²¹ atoms/cm³, and other dopant concentration ranges are within the scope of the disclosure. In some embodiments, a dopant concentration of the second doped region 194 of the drain region 190 is in a range of about 10¹⁸ atoms/cm³ and about 10²¹ atoms/cm³, and other dopant concentration ranges are within the scope of the disclosure.

Returning to FIG. 1B, the method M1 then proceeds to block S90 where a resist protective (RP) layer is formed over the second well region. With reference to FIG. 9, a resist protective layer 220 is formed over the second well region 130. In some embodiments, the resist protective layer 220 is formed of a dielectric layer such as silicon dioxide using chemical vapor deposition (CVD), physical vapor deposition (PVD), atomic layer deposition (ALD), other suitable processes, or combinations thereof.

In some embodiments, the resist protective layer 220 is formed over portion of the gate structure 140, the first and second spacers 170 and 180, extending over a portion of the first doped region 192 of the drain region 190. That is, the resist protective layer 220 covers and in contact with the second well region 130. The resist protective layer 220 is in contact with the gate electrode 144 of the gate structure 140 and first doped region 192 of the drain region 190. The resist protective layer 220 may function as a silicide blocking layer during a subsequent self-aligned silicide (salicide) process discussed below. This protects the areas under the resist protective layer 220 from the silicide formation.

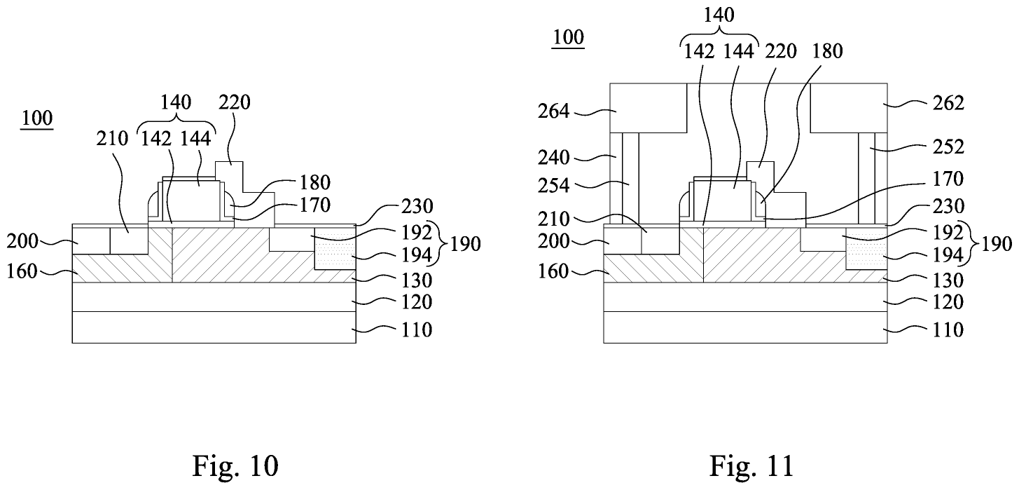

Returning to FIG. 1B, the method M1 then proceeds to block S100 where metal alloy layers are respectively formed over the gate electrode, the bulk region, the source region and the drain region. With reference to FIG. 10, in some embodiments of block S100, metal alloy layers 230 may be formed by self-aligned silicidation (salicide) process. In an exemplary salicide prcocess, a metal material (e.g., cobalt, nickel or other suitable metal) is formed over the semiconductor substrate 110, then the temperature is raised to anneal and cause a reaction between the metal material and the underlying silicon/polysilicon so as to form the metal alloy layers 230, and the un-reacted metal is etched away. The silicide material is self-aligned with the bulk region 200, the source region 210, the drain region 190, and/or the gate electrode 144 to reduce contact resistance.

In some embodiments, one of the metal alloy layers 230 is in contact with the drain region 190 and an edge of the resist protective layer 220. In some embodiments, another one of the metal alloy layers 230 covers the bulk region 200 and the source region 210. In some embodiments, still another one of the metal alloy layers 230 is in contact with a top surface of the gate electrode 144 to lower a resistance of the gate structure 140.

Returning to FIG. 1B, the method M1 then proceeds to block S110 where contacts and metal lines are respectively formed over the metal alloy layers. With reference to FIG. 11, in some embodiments of block S110, an interlayer dielectric (ILD) layer 240 is formed above the structure in FIG. 10. In some embodiments, the ILD layer 240 includes a material having a low dielectric constant such as a dielectric constant less than about 3.9. For example, the ILD layer 240 may include silicon oxide. In some embodiments, the dielectric layer includes silicon dioxide, silicon nitride, silicon oxynitride, polyimide, spin-on glass (SOG), fluoride-doped silicate glass (FSG), carbon doped silicon oxide, Black Diamond® (Applied Materials of Santa Clara, Calif.), Xerogel, Aerogel, amorphous fluorinated carbon, Parylene, BCB (bis-benzocyclobutenes), SiLK (Dow Chemical, Midland, Mich.), polyimide, and/or other suitable materials. The ILD layer 240 layer may be formed by a technique including spin-on coating, CVD, or other suitable processes.

Then, a plurality of contacts 252 and 254 are formed in the ILD layer 240 to contact the metal alloy layers 230. For example, a plurality of the openings are formed in the ILD layer 240, and conductive materials are then deposited in the openings. The excess portions of the conductive materials outside the openings are removed by using a CMP process, while leaving portions in the openings to serve as the contacts 252 and 254. The contacts 252 and 254 may be made of tungsten, aluminum, copper, or other suitable materials. In some embodiments, the contact 252 is electrically connected to the drain region 190, and the contact 254 is electrically connected to the bulk region 200 and the source region 210.

A plurality of metal lines 262 and 264 are formed in the ILD layer 240 to respectively electrically connected the contacts 252 and 254. For example, a plurality of the openings are formed in the ILD layer 240, and conductive materials are then deposited in the openings. The excess portions of the conductive materials outside the openings are removed by using a CMP process, while leaving portions in the openings to serve as the metal lines 262 and 264. In some embodiments, the contacts 252 and 254 and the metal lines 262 and 264 are formed together in one deposition process. For example, first openings are formed in the top portion of the ILD layer 240 and second openings are formed in the bottom portion of the ILD layer 240, in which each of the second openings is communicated to each of the first openings. Then, conductive materials are deposited in the first and second openings to form the metal lines 262 and 264 and the contacts 252 and 254. The metal lines 262 and 264 may be made of tungsten, aluminum, copper, or other suitable materials. In some embodiments, the metal line 262 is electrically connected to the drain region 190 via the contact 252, and the metal line 264 is connected to the bulk region 200 and the source region 210 via the contact 254.

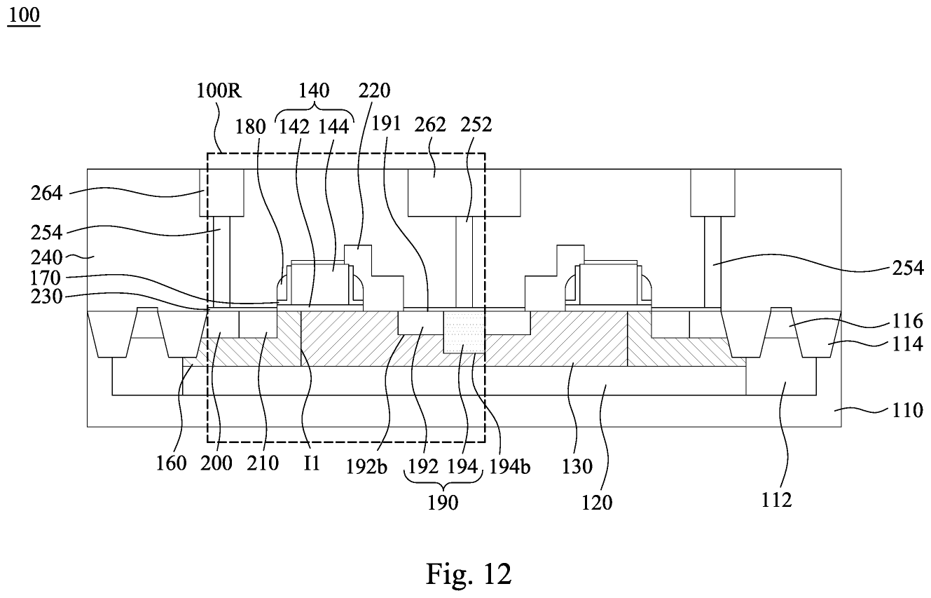

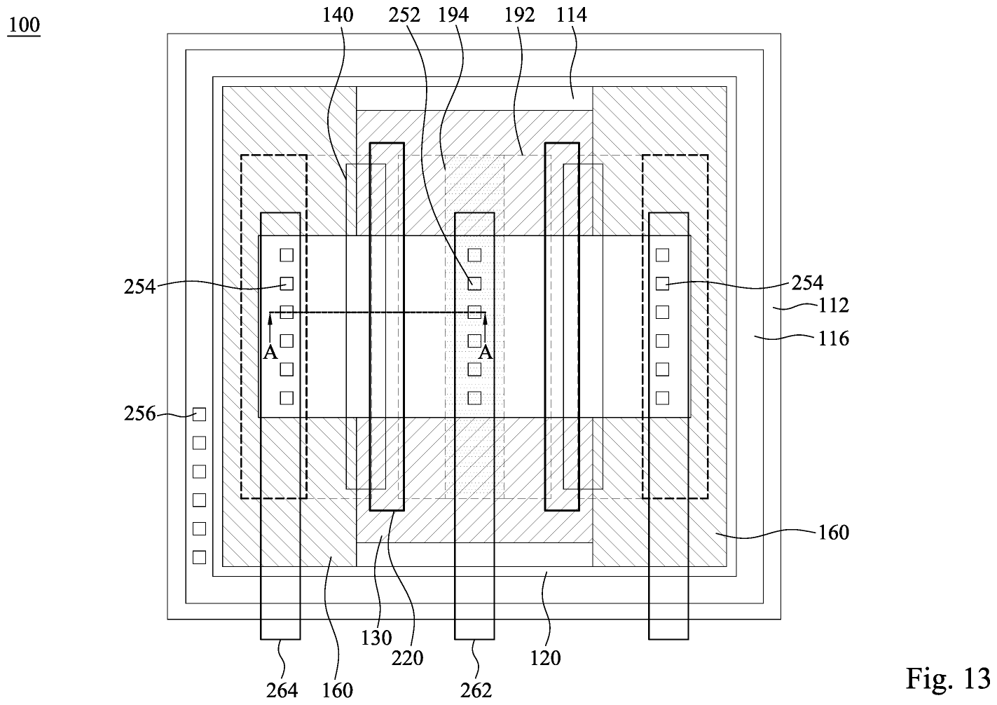

Reference is made to FIGS. 12 and 13, where FIG. 12 is a cross-sectional view of the semiconductor device in accordance with some embodiments, and FIG. 13 is a top view of a layout of the semiconductor device of FIG. 12. The cross-sectional view shown in FIG. 12 is taken along line A-A in FIG. 13. For clarity, the metal alloy layers 230 are omitted in FIG. 13. It is noted that the structure of FIG. 11 corresponds to a region 100R in FIG. 12.

The semiconductor device 100 includes the semiconductor substrate 110, isolation structures 114, the first well region 120, the second well region 130, the third well region 160, the gate structure 140, the drain region 190, and the source region 210. The semiconductor substrate 110 has fourth well regions 112 and doped regions 116. The fourth well regions 112 surrounding the first well region 120. The fourth well regions 112 and the first well region 120 may have the same conductivity type (e.g., P-type) but with different dopant concentrations. For example, the fourth well regions 112 are P-type well regions. In some embodiments, the semiconductor device 100 further includes contacts 256 connected to the doped regions 116. The isolation structures 114 such as shallow trench isolation (STI) or local oxidation of silicon (LOCOS) (or field oxide, FOX) including isolation regions may be formed in the semiconductor substrate 110 to define and electrically isolate various active regions so as to prevent leakage current from flowing between adjacent active regions. In some embodiments, the formation of an STI feature may include dry etching a trench in a substrate and filling the trench with insulator materials such as silicon oxide, silicon nitride, silicon oxynitride, or other suitable materials. The filled trench may have a multi-layer structure such as a thermal oxide liner layer filled with silicon nitride or silicon oxide. In some other embodiments, the STI structure may be created using a processing sequence such as: growing a pad oxide, forming a low pressure chemical vapor deposition (LPCVD) nitride layer, patterning an STI opening using photoresist and masking, etching a trench in the substrate, optionally growing a thermal oxide trench liner to improve the trench interface, filling the trench with CVD oxide, using chemical mechanical polishing (CMP) processing to planarize the CVD oxide, and using a nitride stripping process to remove the silicon nitride. The doped regions 116 are formed over and in contact with the fourth well regions 112. The doped regions 116 and the fourth well regions 112 may have the same conductivity type (e.g., P-type) but with different dopant concentrations. For example, a dopant concentration of the doped regions 116 is greater than a dopant concentration of the fourth well regions 112. In some embodiments, the doped regions 116 and the bulk region 200 are formed in one implantation process and have the same conductivity type (e.g., P-type).

The first well region 120 is in the semiconductor substrate 110. The second well region 130 is over the first well region 120. The third well region 160 is over the first well region 120 and adjacent to the second well region 130. In some embodiments, the second well region 130 has a depth substantially the same as that of the third well region 160. In some embodiments, the first well region 120 and the third well region 160 have the same conductivity type (e.g., P-type). In some embodiments, the third well region 160 has the first conductivity type (e.g., P-type), while the second well region 130 has the second conductivity type (e.g., N-type) different from the first conductivity type.

The gate structure 140 is disposed over the second well region 130 and the third well region 160. The interface I1 of the second well region 130 and the third well region 160 extends downward from the gate structure 140. The gate structure 140 includes the gate dielectric layer 142 and the gate electrode 144 over the gate dielectric layer 142. In some embodiments, the gate structure 140 includes a first portion overlapping the second well region 130 and a second portion overlapping the third well region 160, in which an area of the first portion of the gate structure 140 is greater than the second portion of the gate structure 140. In other words, a vertical projection of the gate dielectric layer 142 of the gate structure 140 on the second well region 130 is greater than a vertical projection of the gate dielectric layer 142 of the gate structure 140 on the third well region 160. The second well region 130 and the third well region 160 are under and in contact with the gate structure 140.

The source region 210 and the drain region 190 are on opposite sides of the gate structure 140. The source region 210 is in the third well region 160. The drain region 190 is in the second well region 130. The drain region 190 includes the first doped region 192 and the second doped region 194 adjacent to the first doped region 192. The first doped region 192 of the drain region 190 is closer to the gate structure 140 than the second doped region 194 of the drain region 190. In other words, the first doped region 192 of the drain region 190 is between the gate structure 140 and the second doped region 194 of the drain region 190. In some embodiments, the first doped region 192 of the drain region 190 is between the source region 210 and the second doped region 194 of the drain region 190. In some embodiments, the second doped region 194 of the drain region 190 has the first conductivity type (e.g., P-type), while the first doped region 192 of the drain region 190 has the second conductivity type (e.g., N-type) different from the first conductivity type. In some embodiments, the depth of the second doped region 194 of the drain region 190 is greater than the depth of the first doped region 192 of the drain region 190. In other words, a bottom surface of 194b of the second doped region 194 of the drain region 190 is lower than a bottom surface of the first doped region 192 of the drain region 190. In some embodiments, the source region 210 and the first doped region 192 of the drain region 190 have the same conductivity type (e.g., N-type), while the source region 210 and the second doped region 194 of the drain region 190 have different conductivity type. In some embodiments, the bulk region 200 is in the third well region 160 and adjacent to the source region 210. The source region 210 is between the bulk region 200 and the drain region 190. The second doped region 194 of the drain region 190 and the bulk region 200 have the same conductivity type (e.g., P-type).

The semiconductor device 100 further includes the resist protective layer 220 over the gate structure 140 and the second well region 130. The resist protective layer 220 extends over a portion of the gate structure 140 and over a portion of the first doped region 192 of the drain region 190. The resist protective layer 220 is in contact with the gate electrode 144, the second well region 130, and the first doped region 192 of the drain region 190. The resist protective layer 220 is spaced apart from the second doped region 194 of the drain region 190. The semiconductor device 100 further includes the metal alloy layers 230 over the bulk region 200, the source region 210, the gate electrode 144, and the drain region 190. The semiconductor device 100 further includes the contacts 252 and 254 and the metal lines 262 and 264. The contact 252 is electrically connected to the drain region 190 and the contact 254 is electrically connected to the bulk region 200 and the source region 210. In some embodiments, a top surface 191 of the drain region 190 is in contact with the resist protective layer 220 and the metal alloy layers 230.

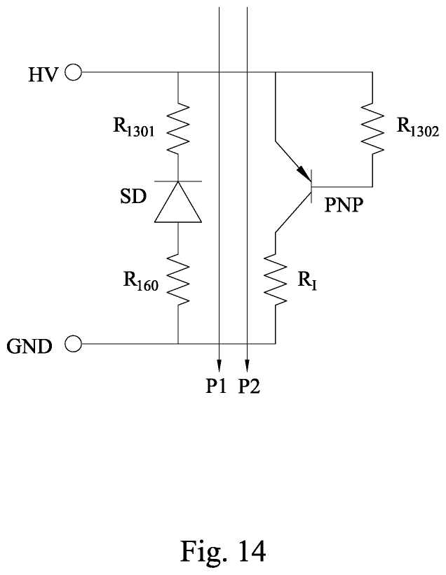

FIG. 14 is an equivalent circuit model of the semiconductor device 100 according to some embodiments of the present disclosure. In FIGS. 12 to 14, when a high voltage HV is applied to the semiconductor device 100, two current paths P1 and P2 are formed. In the current path P1, the current flows through the second well region 130 (which has a resistance R₁₃₀₁), the interface between the second well region 130 and the first well region 120 (which forms a diode SD), and the third well region 160 (which has a resistance R₁₆₀) to the ground GND. In the current path P2, the current flows through the second well region 130 (which has a resistance R₁₃₀₂), a PNP transistor PNP, and the first well region 120 (which has a resistance R_{I}) to the ground GND. In greater detail, due to the configuration of the second doped region 194 of the drain region 190, the second doped region 194, the first well region 120, and the second well region 130 form the PNP transistor PNP, which has low Ron after breakdown, resulting in high discharging capability, low voltage drop, and low surface electric field.

As such, the second doped region 194 of the drain region 190 improves the electrical performance of the semiconductor device 100.

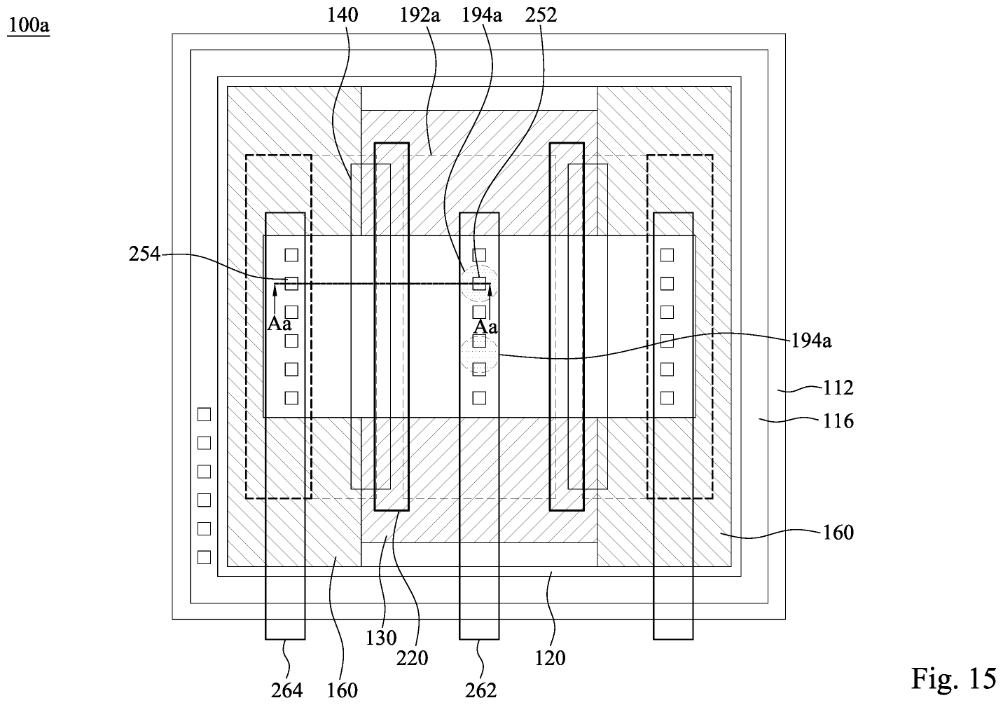

FIG. 15 is a top view of a layout of a semiconductor device 100a in accordance with some embodiments. In some embodiments, FIG. 12 is a cross-sectional view taken along line Aa-Aa in FIG. 15. As shown in FIG. 15, the semiconductor device 100a includes the second well region 130, the third well region 160, the source region in the third well region 160, and a drain region in the second well region 130. The difference between the semiconductor device 100a in FIG. 15 and the semiconductor device 100 in FIG. 13 pertains to the configuration of the second doped region 194. The connection relationships and materials of the drain region, the second well region 130, the third well region 160, and the source region are similar to the semiconductor device 100 shown in FIG. 13 and the description is not repeated hereinafter. For example, the doped regions 194a and the second doped region 194 (see FIG. 13) have the same or similar configurations, and the doped region 192a and the first doped region 192 (see FIG. 13) have the same or similar configurations.

As shown in FIG. 15, the drain region includes doped regions 194a in the second well region 130. The doped regions 194a are spaced apart from each other, and the doped region 192a surrounds the doped regions 194a. Some of the contacts 252 are over the doped region 194a of the drain region, and some of the contacts 252 are over the doped region 192a of the drain region. In some embodiments, the doped region 194a of the drain region has an elliptical profile in the top view. In some embodiments, the doped region 194a of the drain region has a circle profile in the top view.

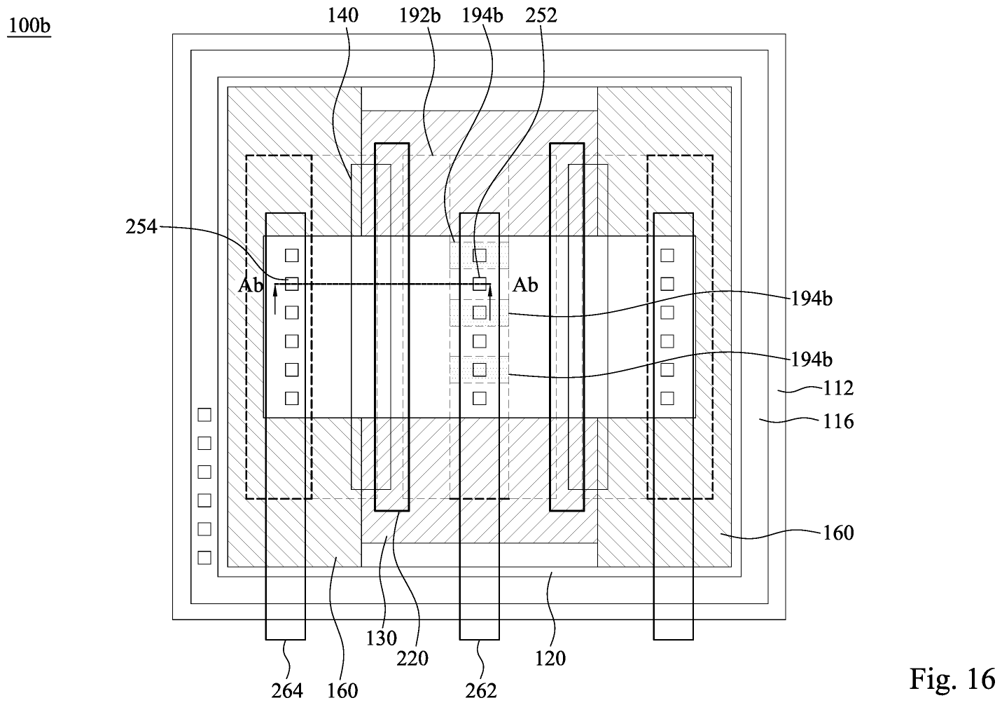

FIG. 16 is a top view of a layout of a semiconductor device 100b in accordance with some embodiments. In some embodiments, FIG. 12 is a cross-sectional view taken along line Ab-Ab in FIG. 16. As shown in FIG. 16, the semiconductor device 100a includes the second well region 130, the third well region 160, the source region in the third well region 160, and a drain region in the second well region 130. The difference between the semiconductor device 100a in FIG. 16 and the semiconductor device 100 in FIG. 13 pertains to the configuration of the second doped region 194. The connection relationships and materials of the drain region, the second well region 130, the third well region 160, and the source region are similar to the semiconductor device 100 shown in FIG. 13 and the description is not repeated hereinafter. For example, the doped regions 194b and the second doped region 194 (see FIG. 13) have the same or similar configurations, and the doped region 192b and the first doped region 192 (see FIG. 13) have the same or similar configurations.

As shown in FIG. 16, the drain region includes doped regions 194b in the second well region 130. The doped regions 194b are spaced apart from each other, and the doped region 192b surrounds the doped regions 194b. Some of the contacts 252 are over the doped region 194b of the drain region. In some embodiments, the doped region 194b of the drain region has a rectangle profile in the top view. In some embodiments, the doped region 194b of the drain region has a square profile in the top view.

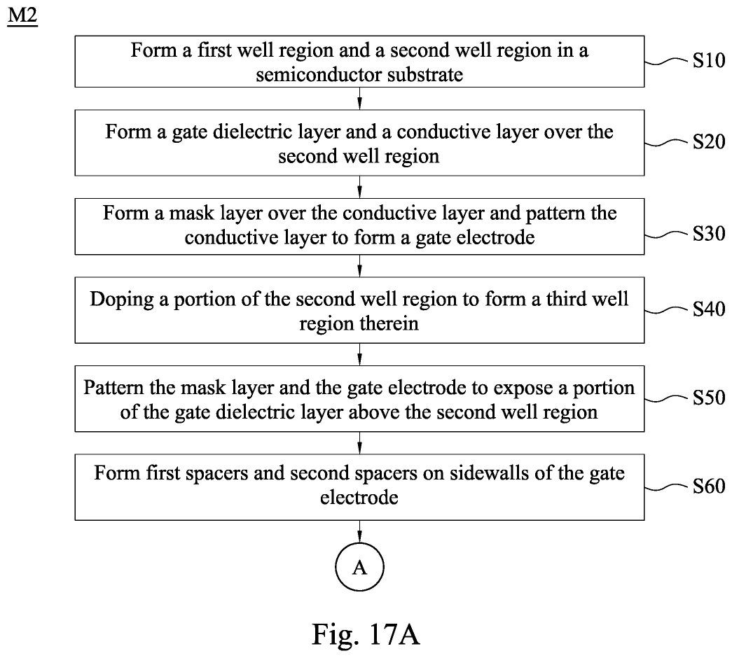

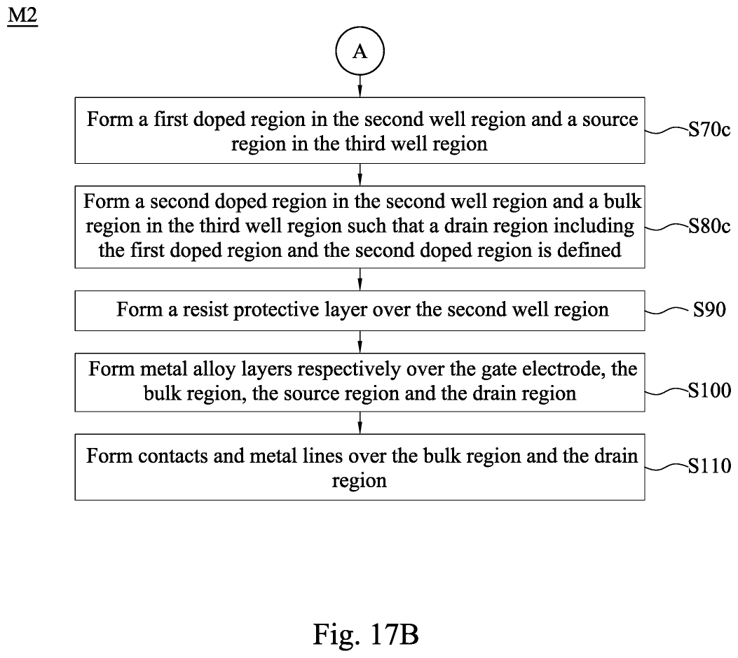

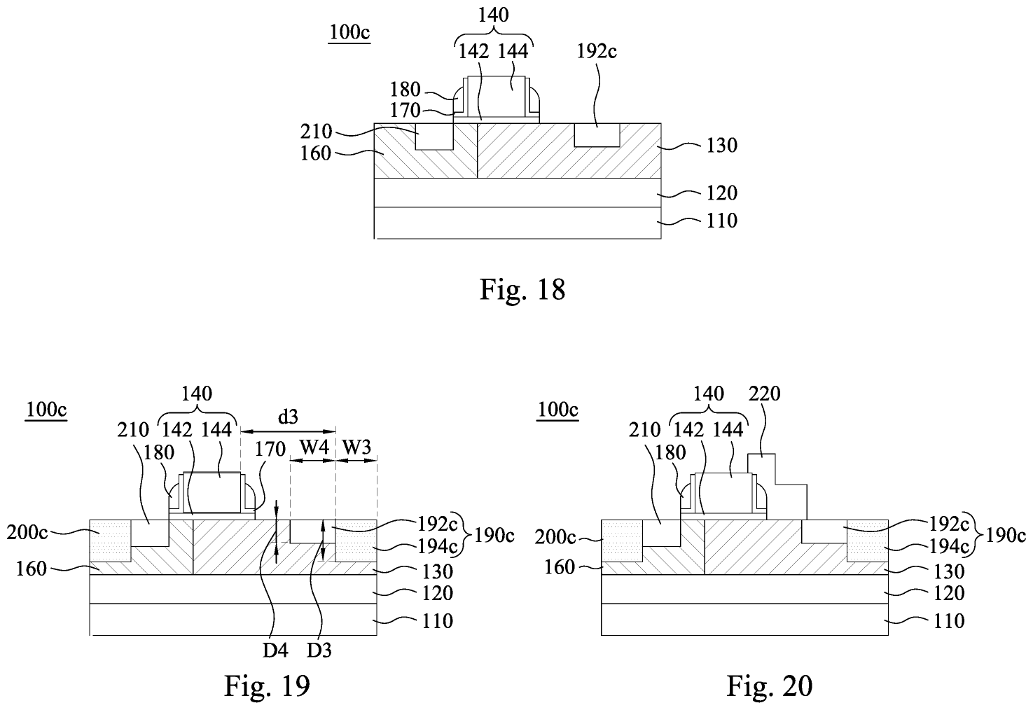

Referring now to FIGS. 17A and 17B, illustrated is an exemplary method M2 for fabrication of a semiconductor device in accordance with some embodiments. FIGS. 18-22 illustrate a semiconductor device 100c fabricated using the method M2. The method M2 includes a relevant part of the entire manufacturing process. It is understood that additional operations may be provided before, during, and after the operations shown by FIGS. 17A and 17B, and some of the operations described below can be replaced or eliminated for additional embodiments of the method. The order of the operations/processes may be interchangeable. The method M2 includes fabrication of a semiconductor device 100c.

With reference to FIG. 18, at block S10, a first well region 120 and a second well region 130 are formed in a semiconductor substrate 110. The first well region 120 may have a first conductivity type (e.g., P-type) such as boron (B), BF₂, BF₃, combinations thereof, or the like. In some embodiments, the first well region 120 is referred as a deep P-type well (DPW). The second well region 130 is formed in the first well region 120. The second well region 130 may have a second conductivity type (e.g., N-type) such as phosphorous (P), arsenic (As), antimony (Sb), combinations thereof, or the like. In some embodiments, the second well region 130 is referred as an N-type doped region (NDD) (or N-type drift region). In some embodiments, the second dopants of the second well region 130 have different conductivity type from the first dopants of the first well region 120. The dopant concentration of the second well region 130 may be greater than the dopant concentration of the first well region 120.

At block S20, a gate dielectric layer and a conductive layer are formed over the semiconductor substrate 110. At block S30, a mask layer is formed over the conductive layer and the conductive layer is patterned to form a gate electrode 144. At block S40, a portion of the second well region 130 is doped to form a third well region 160 therein. In some embodiments, the third well region 160 is doped with first dopants having first conductivity type (e.g., P-type in this case) such as boron (B), BF₂, BF₃, combinations thereof; or the like. The first dopants of the third well region 160 may have the same conductivity type as the first dopants of the first well region 120. At block S50, the mask layer and the gate electrode 144 are patterned a portion of the gate dielectric layer above the second well region 130. At block S60, first spacers 170 and second spacers 180 are formed on sidewalls of the gate electrode 144.

At block S70c, a first doped region 192c is formed in the second well region 130 and a source region 210 is formed in the third well region 160. In some embodiments, a first implantation process is performed to dope second dopants into the second well region 130 and the third well region 160, thus forming the first doped region 192c in the second well region 130 and the source region 210 in the third well region 160. The first implantation process may be performed with second dopants having the second conductivity type (e.g., N-type in this case) into the second well region 130 and the third well region 160 to respectively form the first doped region 192c and the source region 210. The source region 210 and the first doped region 192c may be N+ regions (interchangeably referred to as heavily doped N-type regions) having N-type impurity concentration greater than that of the second well region 130 and the third well region 160. In some embodiments, the source region 210 and the first doped region 192c include N-type dopants such as P or As.

A rapid thermal annealing (RTA) process may be performed after the implantation process to activate the implanted dopants in the bulk region, the source region 210 and the first doped region 192c. In some embodiments, a depth of the first doped region 192c may be substantially the same as a depth of the source region 210.

Returning to FIG. 17B, the method M2 then proceeds to block S80c where a second doped region is formed in the second well region and a bulk region is formed in the third well region such that a drain region including the first doped region and the second doped region is defined. With reference to FIG. 19, in some embodiments of block S80c, a second implantation process is performed to dope first dopants into the second well region 130 and the third well region 160, thus respectively forming a second doped region 194c in the second well region 130 and a bulk region 200c in the third well region 160. The second implantation process may be performed to dope first dopants having first conductivity type (e.g., P-type in this case) into the second well region 130 and the third well region 160 to form the second doped region 194c adjacent to the first doped region 192c and the bulk region 200c adjacent to the source region 210. The first doped region 192c and the second doped region 194c in combination are defined as a drain region 190c. The second doped region 194c and the bulk region 200c may be P+ or heavily doped regions having P-type impurity concentration greater than the second well region 130 and the third well region 160. In some embodiments, the second doped region 194c and the bulk region 200c includes P-type dopants such as boron or boron difluoride (BF₂). A rapid thermal annealing (RTA) process may be performed after the implantation process to activate the implanted dopants in the second doped region 194c and the bulk region 200c.

Since the drain region 190c includes the first doped region 192c and the second doped region 194c adjacent to the first doped region 192c, the discharging capability of the semiconductor device 100c can be increased. Further, lower voltage drop and lower surface electrical field can be achieved.

In some embodiments, a depth D3 of the second doped region 194c of the drain region 190c is greater than a depth D4 of the first doped region 192c of the drain region 190c. In some embodiments, the depth D3 of the second doped region 194c of the drain region 190c is greater than a depth of the source region 210. In some embodiments, the depth D3 of the second doped region 194c of the drain region 190c is substantially the same as a depth of the bulk region 200c. The depth D3 of the second doped region 194c of the drain region 190c is in a range of about 0.01 um to about 4 um, and other depth ranges are within the scope of the disclosure. In some embodiments, the depth of the bulk region 200c is greater than the depth D4 of the first doped region 192c of the drain region 190c and the depth of the source region 210.

In some embodiments, a width W3 of the second doped region 194c of the drain region 190c is in a range of about 0.01 um to about 5 um, and other width ranges are within the scope of the disclosure. In some embodiments, a ratio of the width W3 of the second doped region 194c to a width W4 of the first doped region 192c is in a range of about 0.1 to about 5. In some embodiments, a lateral distance d3 between the gate electrode 144 and the second doped region 194c of the drain region 190c is in a range of 0.01 um to 20 um. In some embodiments, the lateral distance d3 between the gate electrode 144 and the second doped region 194c of the drain region 190c is greater than a lateral distance between the source region 210 and the gate electrode 144, and thus the LDMOS transistor has source/drain regions 210 and 190c asymmetric with respect to the gate structure 140. Moreover, the drain region 190c has a width greater than that of the source region 210.

In some embodiments, a dopant concentration of the first doped region 192c of the drain region 190c is in a range of about 10¹⁸ atoms/cm³ and about 10²¹ atoms/cm³, and other dopant concentration ranges are within the scope of the disclosure. In some embodiments, a dopant concentration of the second doped region 194c of the drain region 190c is in a range of about 10¹⁸ atoms/cm³ and about 10²¹ atoms/cm³, and other dopant concentration ranges are within the scope of the disclosure. In some embodiments, the dopant concentration of the second doped region 194c of the drain region 190c is substantially the same as a dopant concentration of the bulk region 200c since the second doped region 194c of the drain region 190c and the bulk region 200c are formed in one implantation process.

Returning to FIG. 17B, the method M2 then proceeds to block S90 where a resist protective (RP) layer is formed over the second well region. With reference to FIG. 20, a resist protective layer 220 is formed over the second well region 130. Materials, configurations, dimensions, processes and/or operations regarding the resist protective layer 220 of FIG. 20 are similar to or the same as those of FIG. 9, and, therefore, a description in this regard will not be repeated hereinafter.

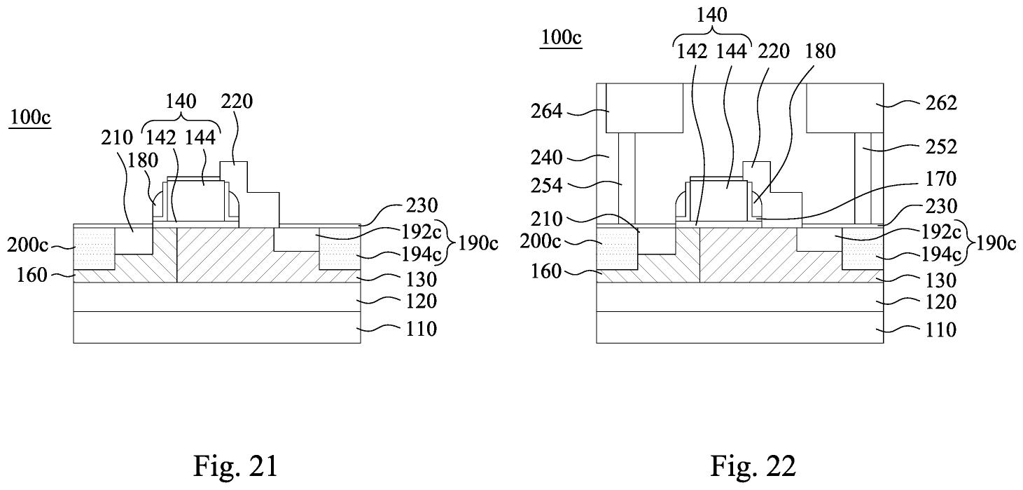

Returning to FIG. 17B, the method M2 then proceeds to block S100 where metal alloy layers are respectively formed over the gate electrode, the bulk region, the source region and the drain region. With reference to FIG. 21, in some embodiments of block S100, metal alloy layers 230 are respectively formed over the gate electrode 144, the bulk region 200c, the source region 210 and the drain region 190c. Materials, configurations, dimensions, processes and/or operations regarding the metal alloy layers 230 of FIG. 21 are similar to or the same as those of FIG. 10, and, therefore, a description in this regard will not be repeated hereinafter.

Returning to FIG. 17B, the method M2 then proceeds to block S110 where contacts and metal lines are respectively formed over the metal alloy layers. With reference to FIG. 22, in some embodiments of block S110, an interlayer dielectric (ILD) layer 240 is formed above the structure in FIG. 21. A plurality of contacts 252 and 254 are formed in the ILD layer 240 to contact the metal alloy layers 230. A plurality of metal lines 262 and 264 are then formed in the ILD layer 240 to respectively electrically connected the contacts 252 and 254. Materials, configurations, dimensions, processes and/or operations regarding the ILD layer 240, the contacts 252 and 254, and the metal lines 262 and 264 of FIG. 22 are similar to or the same as those of FIG. 11, and, therefore, a description in this regard will not be repeated hereinafter.

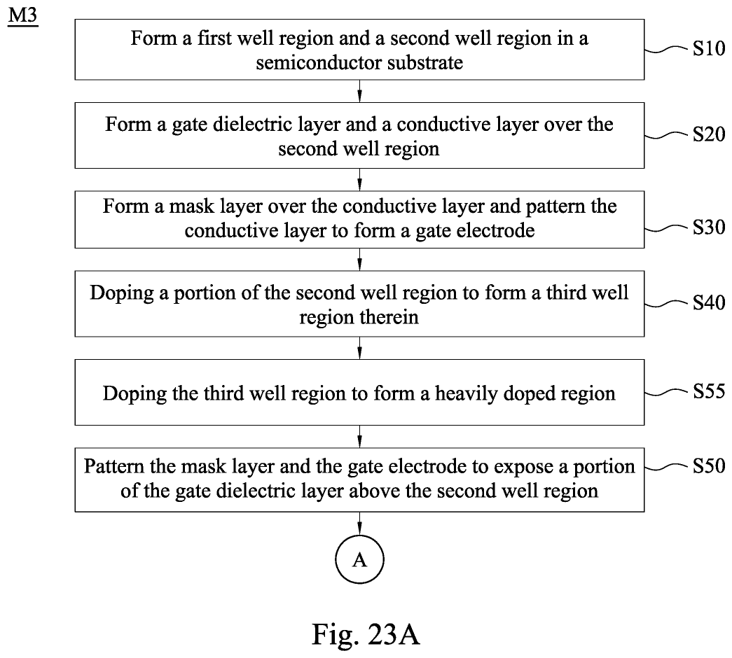

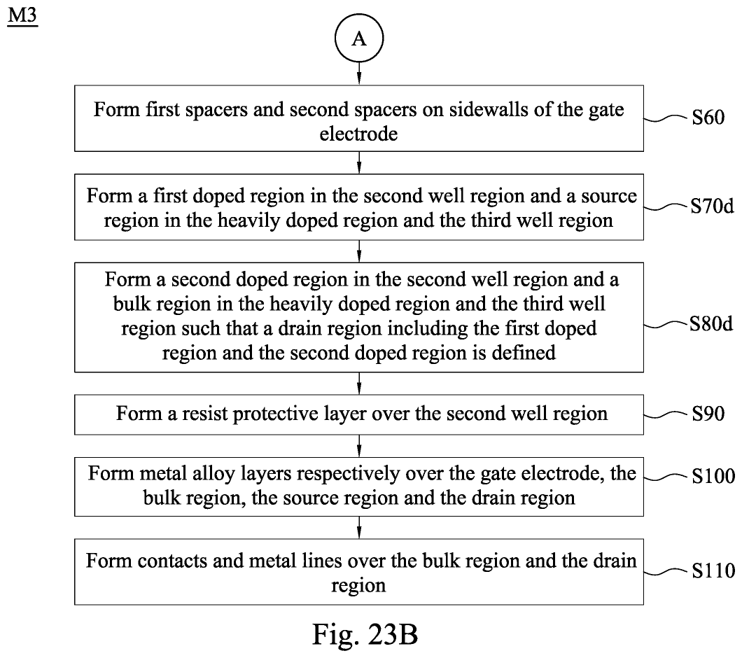

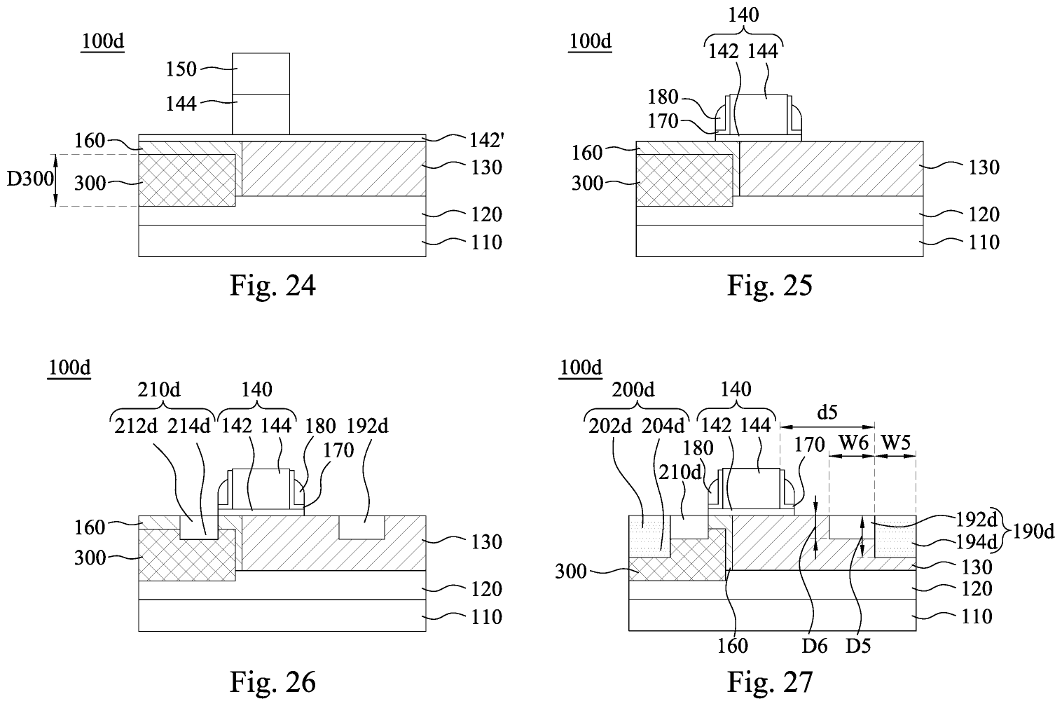

Referring now to FIGS. 23A and 23B, illustrated is an exemplary method M3 for fabrication of a semiconductor device in accordance with some embodiments. FIGS. 24-30 illustrate a semiconductor device 100d fabricated using the method M3. The method M3 includes a relevant part of the entire manufacturing process. It is understood that additional operations may be provided before, during, and after the operations shown by FIGS. 23A and 23B, and some of the operations described below can be replaced or eliminated for additional embodiments of the method. The order of the operations/processes may be interchangeable. The method M3 includes fabrication of a semiconductor device 100d.

With reference to FIG. 24, at block S10, a first well region 120 and a second well region 130 are formed in a semiconductor substrate 110. The first well region 120 may have a first conductivity type (e.g., P-type) such as boron (B), BF₂, BF₃, combinations thereof, or the like. In some embodiments, the first well region 120 is referred as a deep P-type well (DPW). The second well region 130 is formed in the first well region 120. The second well region 130 may have a second conductivity type (e.g., N-type) such as phosphorous (P), arsenic (As), antimony (Sb), combinations thereof, or the like. In some embodiments, the second well region 130 is referred as an N-type doped region (NDD) (or N-type drift region). In some embodiments, the second dopants of the second well region 130 have different conductivity type from the first dopants of the first well region 120. The dopant concentration of the second well region 130 may be greater than the dopant concentration of the first well region 120.

At block S20, a gate dielectric layer and a conductive layer are formed over the semiconductor substrate 110. At block S30, a mask layer is formed over the conductive layer and the conductive layer is patterned to form a gate electrode 144. At block S40, a portion of the second well region 130 is doped to form a third well region 160 therein. In some embodiments, the third well region 160 is doped with first dopants having first conductivity type (e.g., P-type in this case) such as boron (B), BF₂, BF₃, combinations thereof, or the like. The first dopants of the third well region 160 may have the same conductivity type as the first dopants of the first well region 120.

At block S55, the third well region 160 is doped to form a heavily doped region 300. The heavily doped region 300 may be P+ or heavily doped regions having p-type impurity concentration greater than the third well region 160. The heavily doped region 300 may have a dopant concentration is in a range of about 10¹⁷ atoms/cm³ and about 10¹⁹ atoms/cm³. In some embodiments, the heavily doped region 300 includes p-type dopants such as boron or boron difluoride (BF₂). The heavily doped region 300 may be formed by a method such as ion implantation or diffusion. A rapid thermal annealing (RTA) process may be performed after the implantation process to activate the implanted dopant. As illustrated in FIG. 24, the heavily doped region 300 is formed in the third well region 160 and the first well region 120. The heavily doped region 300 has a first portion in the third well region 160 and a second portion in the first well region 120, in which an area of the first portion is greater than an area of the second portion. The heavily doped region 300 has a depth D300 in a range of about 0.1 um to about 10 um. After the heavily doped region 300 is formed, the mask layer 150 is removed. For example, the mask layer 150 is stripped by ashing if it is a photoresist. At block S50, the mask layer 150 and the gate electrode 144 are patterned to expose a portion of the gate dielectric layer 142′ above the second well region 130.

Returning to FIG. 23B, the method M3 then proceeds to block S60 where first spacers and second spacers are formed on sidewalls of the gate electrode. With reference to FIG. 25, in some embodiments of block S60, first spacers 170 are formed on sidewalls of the gate electrode and then second spacers 180 are formed on the first spacer 170. Materials, configurations, dimensions, processes and/or operations regarding the first spacers 170 and the second spacers 180 of FIG. 25 are similar to or the same as those of FIG. 6, and, therefore, a description in this regard will not be repeated hereinafter.

Returning to FIG. 23B, the method M3 then proceeds to block S70d where a first doped region is formed in the second well region and a source region is formed in the heavily doped region and the third well region. With reference to FIG. 26, in some embodiments of block S70d, a first doped region 192d is formed in the second well region 130 and a source region 210d is formed in the heavily doped region 300 and the third well region 160. In some embodiments, a first implantation process is performed to dope second dopants into the second well region 130, thus forming the first doped region 192d in the second well region 130. Further, the first implantation process is also performed to dope the second dopants into the third well region 160 and the heavily doped region 300, thus forming the source region 210d in the third well region 160 and the heavily doped region 300. The first implantation process may be performed with second dopants having the second conductivity type (e.g., N-type in this case) into the second well region 130 to form the first doped region 192d and into the second well region 130 and the heavily doped region 300 to form the source region 210d. The source region 210d and the first doped region 192d may be N+ regions (interchangeably referred to as heavily doped N-type regions) having N-type impurity concentration greater than that of the second well region 130, the third well region 160, and the heavily doped region 300. In some embodiments, the source region 210d and the first doped region 192d include N-type dopants such as P or As. In some embodiments, the source region 210d has an upper portion 212d in the third well region 160 and a lower portion 214d in the heavily doped region 300, in which the upper portion 212d has an area greater than that of the lower portion 214d. In some other embodiments, the area of the upper portion 212d of the source region 210d is substantially the same as the area of the lower portion 214d of the source region 210d.

A rapid thermal annealing (RTA) process may be performed after the implantation process to activate the implanted dopants in the source region 210d and the first doped region 192d. In some embodiments, a depth of the first doped region 192d may be substantially the same as a depth of the source region 210d.

Returning to FIG. 23B, the method M3 then proceeds to block S80d where a second doped region is formed in the second well region and a bulk region is formed in the heavily doped region and the third well region such that a drain region including the first doped region and the second doped region is defined. With reference to FIG. 27, in some embodiments of block S80d, a second implantation process is performed to dope first dopants into the second well region 130 thus forming the second doped region 194d in the second well region 130. Further, the second implantation process is also performed to dope the first dopants into the third well region 160 and the heavily doped region 300, thus forming the bulk region 200d in the third well region 160 and the heavily doped region 300. The second implantation process may be performed to dope first dopants having first conductivity type (e.g., P-type in this case) into the second well region 130 to form the second doped region 194d adjacent to the first doped region 192d and into the third well region 160 and the heavily doped region 300 to form the bulk region 200d adjacent to the source region 210d. The first doped region 192d and the second doped region 194d in combination are defined as a drain region 190d. The second doped region 194d and the bulk region 200d may be P+ or heavily doped regions having P-type impurity concentration greater than the second well region 130, the third well region 160 and the heavily doped region 300. In some embodiments, the second doped region 194d and the bulk region 200d includes P-type dopants such as boron or boron difluoride (BF₂). A rapid thermal annealing (RTA) process may be performed after the implantation process to activate the implanted dopants in the second doped region 194d and the bulk region 200d.

Since the drain region 190d includes the first doped region 192d and the second doped region 194d adjacent to the first doped region 192d, the discharging capability of the semiconductor device 100d can be increased. Further, lower voltage drop and lower surface electrical field can be achieved.

In some embodiments, the bulk region 200d has an upper portion 202d in the third well region 160 and a lower portion 204d in the heavily doped region 300, in which the upper portion 202d has an area greater than that of the lower portion 204d. In some other embodiments, the area of the upper portion 202d of the bulk region 200d is substantially the same as the area of the lower portion 204d of the bulk region 200d. In some embodiments, the heavily doped region 300 is below the bulk region 200d and the source region 210d.

In some embodiments, a depth D5 of the second doped region 194d of the drain region 190d is greater than a depth D6 of the first doped region 192d of the drain region 190d. In some embodiments, the depth D5 of the second doped region 194d of the drain region 190d is greater than a depth of the source region 210d. In some embodiments, the depth D5 of the second doped region 194d of the drain region 190d is substantially the same as a depth of the bulk region 200d. The depth D5 of the second doped region 194d of the drain region 190d is in a range of about 0.01 um to about 4 um, and other depth ranges are within the scope of the disclosure.

In some embodiments, a width W5 of the second doped region 194d of the drain region 190d is in a range of about 0.01 um to about 5 um, and other width ranges are within the scope of the disclosure. In some embodiments, a ratio of the width W5 of the second doped region 194d to a width W6 of the first doped region 192d is in a range of about 0.1 to about 5. In some embodiments, a lateral distance d5 between the gate electrode 144 and the second doped region 194d of the drain region 190d is in a range of 0.01 um to 20 um. In some embodiments, the lateral distance d5 between the gate electrode 144 and the second doped region 194d of the drain region 190d is greater than a lateral distance between the source region 210d and the gate electrode 144, and thus the LDMOS transistor has source/drain regions 210d and 190d asymmetric with respect to the gate structure 140. Moreover, the drain region 190d has a width greater than that of the source region 210d.

In some embodiments, a dopant concentration of the first doped region 192d of the drain region 190d is in a range of about 10¹⁸ atoms/cm³ and about 10²¹ atoms/cm³, and other dopant concentration ranges are within the scope of the disclosure. In some embodiments, a dopant concentration of the second doped region 194d of the drain region 190d is in a range of about 10¹⁸ atoms/cm³ and about 10²¹ atoms/cm³, and other dopant concentration ranges are within the scope of the disclosure.

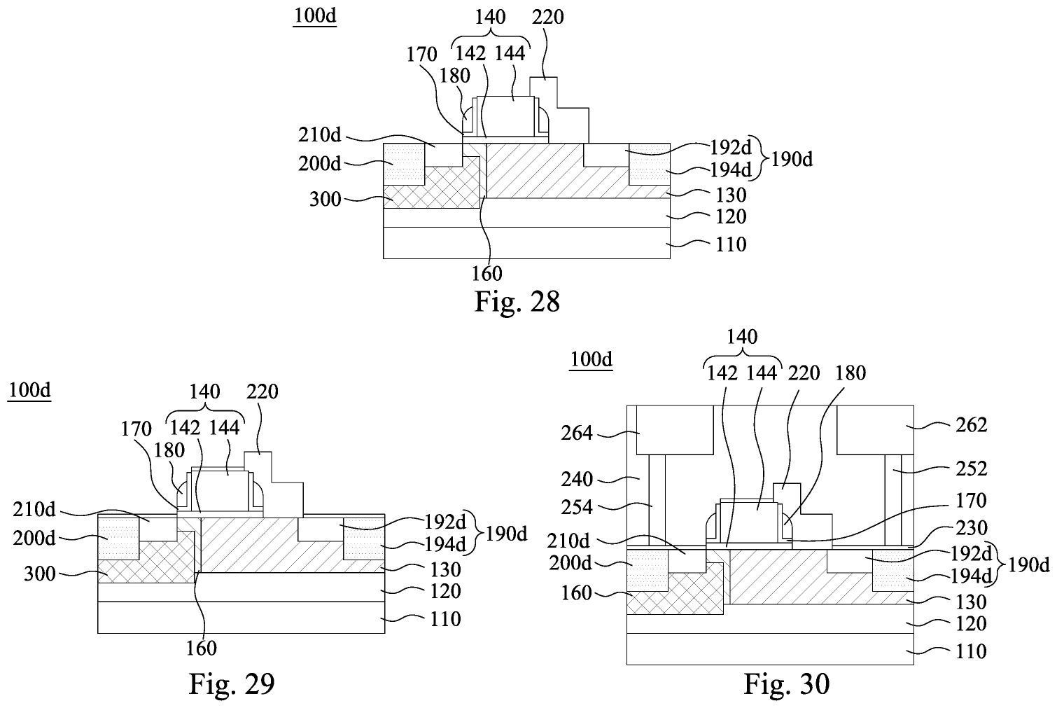

Returning to FIG. 23B, the method M3 then proceeds to block S90 where a resist protective (RP) layer is formed over the second well region. With reference to FIG. 28, a resist protective layer 220 is formed over the second well region 130. Materials, configurations, dimensions, processes and/or operations regarding the resist protective layer 220 of FIG. 28 are similar to or the same as those of FIG. 9, and, therefore, a description in this regard will not be repeated hereinafter.

Returning to FIG. 23B, the method M3 then proceeds to block S100 where metal alloy layers are respectively formed over the gate electrode, the bulk region, the source region and the drain region. With reference to FIG. 29, in some embodiments of block S100, metal alloy layers 230 are respectively formed over the gate electrode 144, the bulk region 200d, the source region 210d and the drain region 190d. Materials, configurations, dimensions, processes and/or operations regarding the metal alloy layers 230 of FIG. 29 are similar to or the same as those of FIG. 10, and, therefore, a description in this regard will not be repeated hereinafter.

Returning to FIG. 23B, the method M3 then proceeds to block S110 where contacts and metal lines are respectively formed over the metal alloy layers. With reference to FIG. 30, in some embodiments of block Si 10, an interlayer dielectric (ILD) layer 240 is formed above the structure in FIG. 29. A plurality of contacts 252 and 254 are formed in the ILD layer 240 to contact the metal alloy layers 230. A plurality of metal lines 262 and 264 are then formed in the ILD layer 240 to respectively electrically connected the contacts 252 and 254. Materials, configurations, dimensions, processes and/or operations regarding the ILD layer 240, the contacts 252 and 254, and the metal lines 262 and 264 of FIG. 30 are similar to or the same as those of FIG. 11, and, therefore, a description in this regard will not be repeated hereinafter.

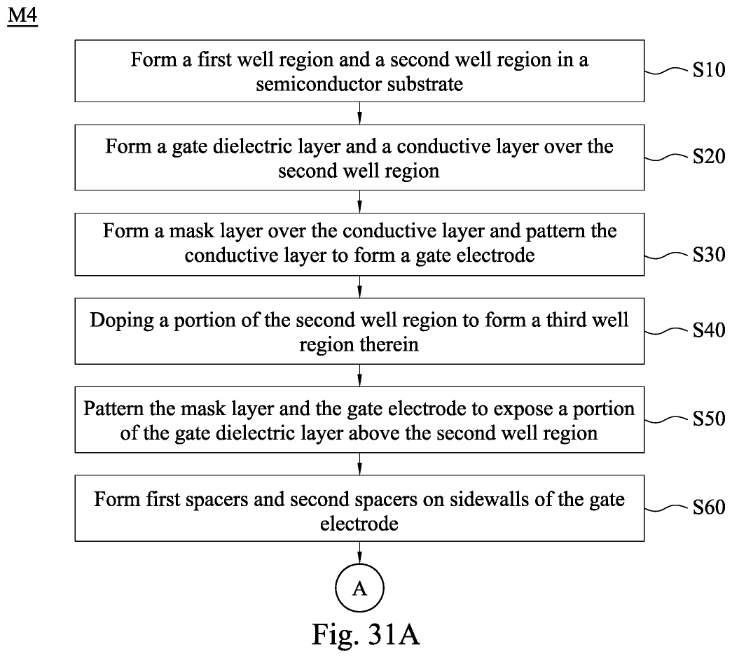

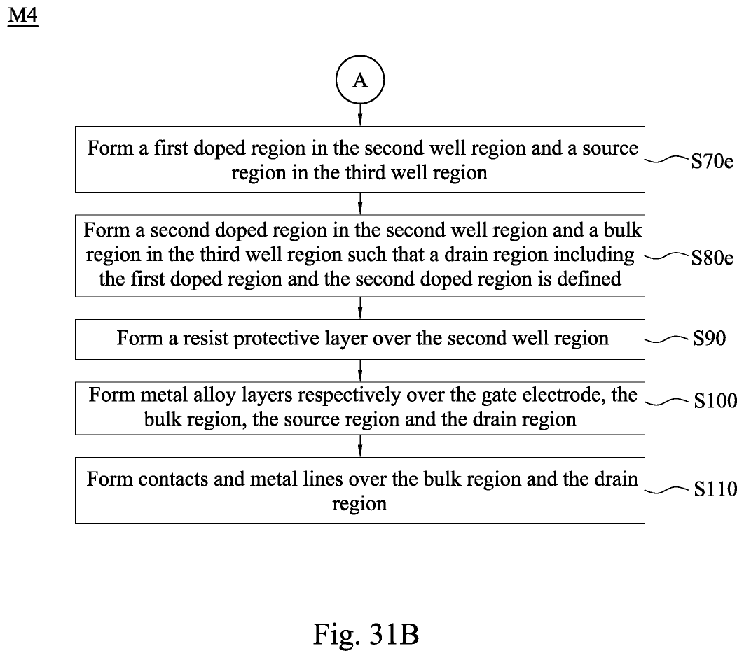

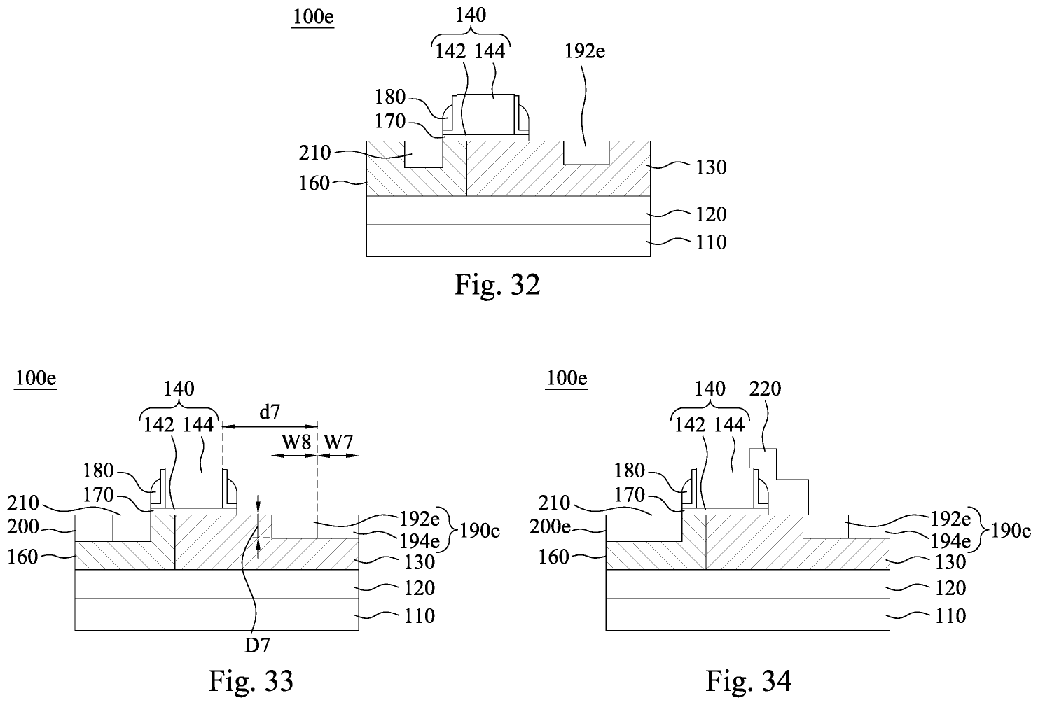

Referring now to FIGS. 31A and 31B, illustrated is an exemplary method M4 for fabrication of a semiconductor device in accordance with some embodiments. FIGS. 32-36 illustrate a semiconductor device 100e fabricated using the method M4. The method M4 includes a relevant part of the entire manufacturing process. It is understood that additional operations may be provided before, during, and after the operations shown by FIGS. 31A and 31B, and some of the operations described below can be replaced or eliminated for additional embodiments of the method. The order of the operations/processes may be interchangeable. The method M4 includes fabrication of a semiconductor device 100e.

With reference to FIG. 32, at block S10, a first well region 120 and a second well region 130 are formed in a semiconductor substrate 110. The first well region 120 may have a first conductivity type (e.g., P-type) such as boron (B), BF₂, BF₃, combinations thereof, or the like. In some embodiments, the first well region 120 is referred as a deep P-type well (DPW). The second well region 130 is formed in the first well region 120. The second well region 130 may have a second conductivity type (e.g., N-type) such as phosphorous (P), arsenic (As), antimony (Sb), combinations thereof, or the like. In some embodiments, the second well region 130 is referred as an N-type doped region (NDD) (or N-type drift region). In some embodiments, the second dopants of the second well region 130 have different conductivity type from the first dopants of the first well region 120. The dopant concentration of the second well region 130 may be greater than the dopant concentration of the first well region 120.

At block S20, a gate dielectric layer and a conductive layer are formed over the semiconductor substrate 110. At block S30, a mask layer is formed over the conductive layer and the conductive layer is patterned to form a gate electrode 144. At block S40, a portion of the second well region 130 is doped to form a third well region 160 therein. In some embodiments, the third well region 160 is doped with first dopants having first conductivity type (e.g., P-type in this case) such as boron (B), BF₂, BF₃, combinations thereof, or the like. The first dopants of the third well region 160 may have the same conductivity type as the first dopants of the first well region 120. At block S50, the mask layer 150 and the gate electrode 144 are patterned to expose a portion of the gate dielectric layer 142′ above the second well region 130. At block S60, first spacers 170 and second spacers 180 are formed on sidewalls of the gate electrode 144.

At block S70e, a first doped region 192e is formed in the second well region 130 and a source region 210 is formed in the third well region 160. In some embodiments, an implantation process is performed to dope second dopants into the second well region 130 and the third well region 160, thus respectively forming the first doped region 192e in the second well region 130 and the source region 210 in the third well region 160. The implantation process may be performed with second dopants having the second conductivity type (e.g., N-type in this case) into the second well region 130 to form the first doped region 192e and into the third well region 160 to form the source region 210. The source region 210 and the first doped region 192e may be N+ regions (interchangeably referred to as heavily doped N-type regions) having N-type impurity concentration greater than that of the second well region 130 and the third well region.

A rapid thermal annealing (RTA) process may be performed after the implantation process to activate the implanted dopants in the source region 210 and the first doped region 192e. In some embodiments, a depth of the first doped region 192e may be substantially the same as a depth of the source region 210.

Returning to FIG. 31B, the method M4 then proceeds to block S80e where a second doped region is formed in the second well region and a bulk region is formed in the third well region such that a drain region including the first doped region and the second doped region is defined. With reference to FIG. 33, in some embodiments of block S80e, an implantation process is performed to dope first dopants into the second well region 130 and the third well region 160, thus respectively forming the second doped region 194e in the second well region 130 and the bulk region 200 in the third well region 160. The implantation process may be performed to dope first dopants having first conductivity type (e.g., P-type in this case) into the second well region 130 to form the second doped region 194e adjacent to the first doped region 192e and into the third well region I60 to form the bulk region 200 adjacent to the source region 210. The first doped region 192e and the second doped region 194e in combination are defined as a drain region 190e. The second doped region 194e and the bulk region 200 may be P+or heavily doped regions having P-type impurity concentration greater than the second well region 130 and the third well region 160. In some embodiments, the second doped region 194e and the bulk region 200 includes P-type dopants such as boron or boron difluoride (BF₂). A rapid thermal annealing (RTA) process may be performed after the implantation process to activate the implanted dopants in the second doped region 194e and the bulk region 200.

Since the drain region 190e includes the first doped region 192e and the second doped region 194e adjacent to the first doped region 192e, the discharging capability can be increased. Further, lower voltage drop and lower surface electrical field can be achieved.

In some embodiments, a depth D7 of the second doped region 194e of the drain region 190e is substantially the same as a depth (i.e., depth D7) of the first doped region 192e of the drain region 190e. In some embodiments, the depth D7 of the second doped region 194e of the drain region 190e, a depth of the source region 210, and a depth of the bulk region 200 are substantially the same. The depth D7 of the second doped region 194e (or the first doped region 192e) of the drain region 190e is in a range of about 0.01 um to about 0.5 um, and other depth ranges are within the scope of the disclosure.

In some embodiments, a width W7 of the second doped region 194e of the drain region Ie is in a range of about 0.01 um to about 5 um, and other width ranges are within the scope of the disclosure. In some embodiments, a ratio of the width W7 of the second doped region 194e to a width W8 of the first doped region 192e is in a range of about 0.1 to about 5. In some embodiments, a lateral distance d7 between the gate electrode 144 and the second doped region 1e of the drain region 190e is in a range of 0.01 um to 20 um. In some embodiments, the lateral distance d7 between the gate electrode 144 and the second doped region 194e of the drain region 190e is greater than a lateral distance between the source region 210 and the gate electrode 144, and thus the LDMOS transistor has source/drain regions 210 and 190e asymmetric with respect to the gate structure 140. Moreover, the drain region 190e has a width greater than that of the source region 210.

In some embodiments, a dopant concentration of the first doped region 192e of the drain region 190e is in a range of about 10¹⁹ atoms/cm³ and about 10²¹ atoms/cm³, and other dopant concentration ranges are within the scope of the disclosure. In some embodiments, a dopant concentration of the second doped region 194e of the drain region 190e is in a range of about 10¹⁹ atoms/cm³ and about 10²¹ atoms/cm³, and other dopant concentration ranges are within the scope of the disclosure.

Returning to FIG. 31B, the method M4 then proceeds to block S90 where a resist protective (RP) layer is formed over the second well region. With reference to FIG. 34, a resist protective layer 220 is formed over the second well region 130. Materials, configurations, dimensions, processes and/or operations regarding the resist protective layer 220 of FIG. 34 are similar to or the same as those of FIG. 9, and, therefore, a description in this regard will not be repeated hereinafter.

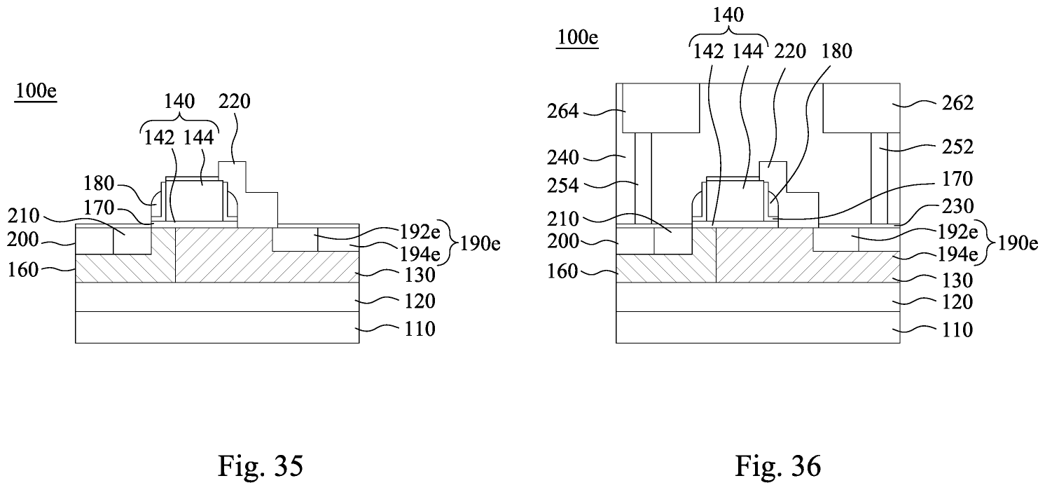

Returning to FIG. 31B, the method M4 then proceeds to block S100 where metal alloy layers are respectively formed over the gate electrode, the bulk region, the source region and the drain region. With reference to FIG. 35, in some embodiments of block S100, metal alloy layers 230 are respectively formed over the gate electrode 144, the bulk region 200, the source region 210 and the drain region 190e. Materials, configurations, dimensions, processes and/or operations regarding the metal alloy layers 230 of FIG. 35 are similar to or the same as those of FIG. 10, and, therefore, a description in this regard will not be repeated hereinafter.

Returning to FIG. 31B, the method M4 then proceeds to block S110 where contacts and metal lines are respectively formed over the metal alloy layers. With reference to FIG. 36, in some embodiments of block S110, an interlayer dielectric (ILD) layer 240 is formed above the structure in FIG. 35. A plurality of contacts 252 and 254 are formed in the ILD layer 240 to contact the metal alloy layers 230. A plurality of metal lines 262 and 264 are then formed in the ILD layer 240 to respectively electrically connected the contacts 252 and 254. Materials, configurations, dimensions, processes and/or operations regarding the ILD layer 240, the contacts 252 and 254, and the metal lines 262 and 264 of FIG. 36 are similar to or the same as those of FIG. 11, and, therefore, a description in this regard will not be repeated hereinafter.

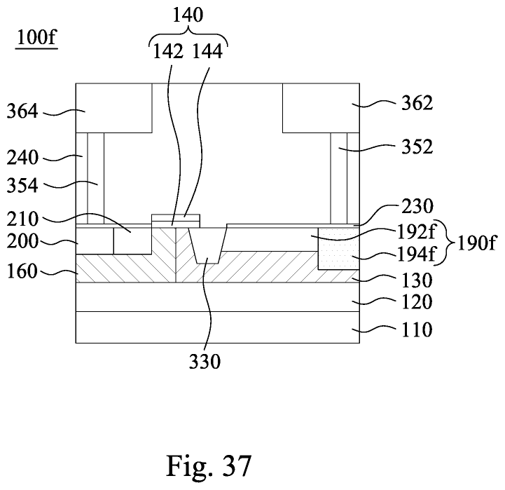

FIG. 37 is a cross-sectional view of a semiconductor device 100f in accordance with some embodiments. As shown in FIG. 37, the semiconductor device 100f includes the semiconductor substrate 110, the first well region 120, the second well region 130, the third well region 160, the gate structure 140 over the second well region 130 and the third well region 160, the source region 210 in the third well region 160, a drain region 190f in the second well region 130, and an isolation structure 330 between the gate structure 140 and the drain region 190f. The difference between the semiconductor device 100f in FIG. 37 and the semiconductor device 100 in FIG. 11 pertains to the structure of the isolation structure 330. The connection relationships and materials of the semiconductor substrate 110, the first well region 120, the second well region 130, the third well region 160, the gate structure 140, and the source region 210 are similar to the semiconductor device 100 shown in FIG. 11 and the description is not repeated hereinafter.

As shown in FIG. 37, the drain region 190f includes a first doped region 192f and a second doped region 194f adjacent to the first doped region 192f. The first doped region 192f may be N+regions (interchangeably referred to as heavily doped N-type regions) having N-type impurity concentration greater than that of the second well region 130. The second doped region 194f may be P+ or heavily doped regions having P-type impurity concentration greater than the second well region 130. In some embodiments, the first doped region 192f and the second doped region 194f have different conductivity type.

In some embodiments, a depth of the second doped region 194f of the drain region 190f is greater than a depth of the first doped region 192f of the drain region 1f. In some embodiments, the depth of the second doped region 194f of the drain region 190f is greater than the source region 210. In some embodiments, a width of the second doped region 194f of the drain region 190f is smaller than a width of the first doped region 192f of the drain region 190f. In some embodiments, the drain region 190f has a width greater than that of the source region 210.

In some embodiments, the isolation structure 330 is between the gate structure 140 and the drain region 190f. The isolation structure 330 is in contact with the gate structure 140 and the first doped region 1f of the drain region 190f. The gate structure 140 has a portion overlapping the isolation structure 330. In other words, the isolation structure 330 has a first portion covered by the gate structure 140 and a second portion covered by the ILD layer 240. In some embodiments, the semiconductor device includes a plurality of contacts 352 and 354 and a plurality of metal lines 362 and 364. The contacts 352 and 354 are respectively electrically connected to the first doped region 192f of the drain region 190f and the second doped region 194f of the drain region 190f. The contacts 356 and 358 are respectively electrically connected to the source region 210 and the bulk region 200. The metal line 362 is electrically connected to the drain region 190f via the contacts 352 and 354, and the metal line 364 is electrically connected to the source region 210 and the bulk region 200 via the contacts 356 and 358.

In some embodiments, the first doped region 192f of the drain region 190f has the first conductivity type (P-type) and the second doped region 194f of the drain region 190f has the second conductivity type (N-type). The first doped region 192f of the drain region 190f and the source region 210 may have the same conductivity type. The second doped region 194f of the drain region 190f and the bulk region 200 may have the same conductivity type. Further, in some embodiments, the resist protective layer 220 (see FIG. 11) is omitted.

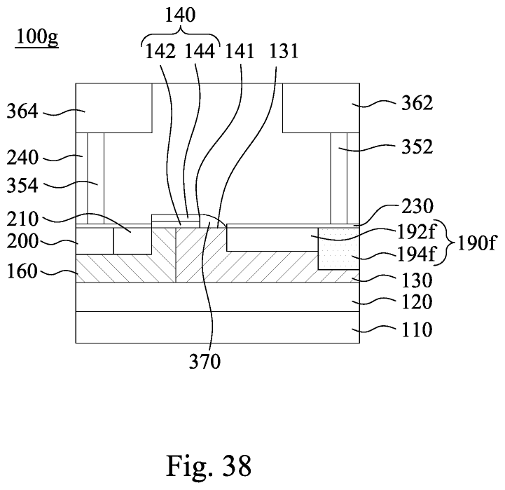

FIG. 38 is a cross-sectional view of a semiconductor device 100g in accordance with some embodiments. As shown in FIG. 38, the semiconductor device 100g includes the semiconductor substrate 110, the first well region 120, the second well region 130, the third well region 160, the gate structure 140 over the second well region 130 and the third well region 160, a spacer 370 on a sidewall 141 of the gate structure 140, the source region 210 in the third well region 160, and the drain region 190f in the second well region 130. The difference between the semiconductor device 100g in FIG. 38 and the semiconductor device 100f in FIG. 37 pertains to the structure of the spacer 370. The connection relationships and materials of the semiconductor substrate 110, the first well region 120, the second well region 130, the third well region 160, the gate structure 140, the source region 210, and the drain region 190f are similar to the semiconductor device 100f shown in FIG. 37 and the description is not repeated hereinafter.

As shown in FIG. 38, the spacer 370 is on the sidewall 141 of the gate structure 140 and extending to the first doped region 192f of the drain region 190f such that an implantation process of forming the first doped region 192f of the drain region 190f is self-aligned. In some embodiments, the spacer 370 covers a portion of the second well region 130 and a top surface 131 of the second well region 130 is covered by the gate structure 140 and the spacer 370. In some embodiments, the spacer 370 is formed of a dielectric layer such as silicon dioxide using chemical vapor deposition (CVD), physical vapor deposition (PVD), atomic layer deposition (ALD), other suitable processes, or combinations thereof.

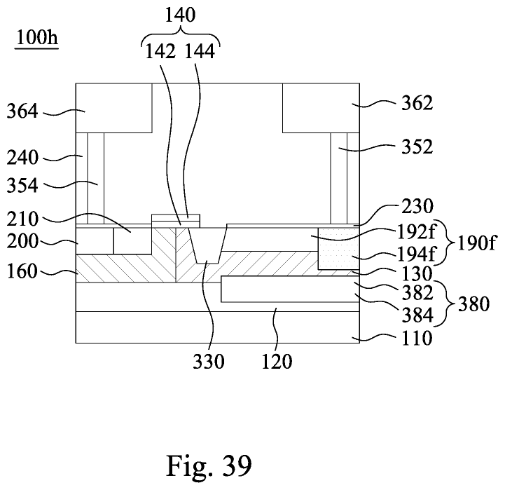

FIG. 39 is a cross-sectional view of a semiconductor device 100h in accordance with some embodiments. As shown in FIG. 39, the semiconductor device 100h includes the semiconductor substrate 110, the first well region 120, the second well region 130, the third well region 160, a heavily doped region 380 in the first and second well regions 120 and 130, the gate structure 140 over the second well region 130 and the third well region 160, the source region 210 in the third well region 160, the drain region 190f in the second well region 130, and the isolation structure 330 adjacent to the drain region 190f. The difference between the semiconductor device 100h in FIG. 39 and the semiconductor device 100f in FIG. 37 pertains to the presence of a heavily doped region 380. The connection relationships and materials of the semiconductor substrate 110, the first well region 120, the second well region 130, the third well region 160, the gate structure 140, the source region 210, isolation structure 330, and the drain region 190f are similar to the semiconductor device 100f shown in FIG. 37 and the description is not repeated hereinafter.

As shown in FIG. 39, the heavily doped region 380 may be P+or heavily doped regions having p-type impurity concentration greater than the first well region 120. In some embodiments, the heavily doped region 380 includes p-type dopants such as boron or boron difluoride (BF₂). The heavily doped region 380 may be formed by a method such as ion implantation or diffusion. A rapid thermal annealing (RTA) process may be performed after the implantation process to activate the implanted dopant. The heavily doped region 380 is formed in the first well region 120 and the second well region 130. The heavily doped region 380 has an upper portion 382 in the first well region 120 and a lower portion 384 in the second well region 130, in which an area of the upper portion 382 is smaller than an area of the lower portion 384. In some embodiments, the heavily doped region 380 is below the second doped region 194f of the drain region 190.

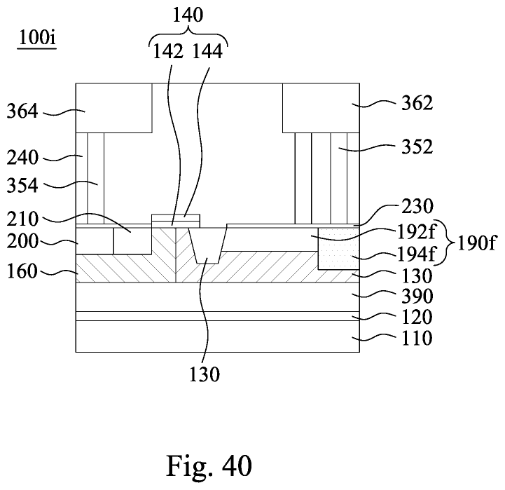

FIG. 40 is a cross-sectional view of a semiconductor device 100i in accordance with some embodiments. As shown in FIG. 40, the semiconductor device 100i includes the semiconductor substrate 110, the first well region 120, the second well region 130, the third well region 160, a P-type well region 390, the gate structure 140 over the second well region 130 and the third well region 160, the source region 210 in the third well region 160, the drain region 190f in the second well region 130, and the isolation structure 330 adjacent to the drain region 190f. The difference between the semiconductor device 100i in FIG. 40 and the semiconductor device 100f in FIG. 37 pertains to the presence of a P-type well region 390. The connection relationships and materials of the semiconductor substrate 110, the first well region 120, the second well region 130, the third well region 160, the gate structure 140, the source region 210, isolation structure 330, and the drain region 190f are similar to the semiconductor device 100f shown in FIG. 37 and the description is not repeated hereinafter.

As shown in FIG. 40, the P-type well region 390 may be heavily doped regions having p-type impurity concentration greater than the first well region 120. In some embodiments, the P-type well region 390 includes p-type dopants such as boron or boron difluoride (BF₂). The P-type well region 390 may be formed by a method such as ion implantation or diffusion. A rapid thermal annealing (RTA) process may be performed after the implantation process to activate the implanted dopant. In some embodiments, the P-type well region 390 and the second well region 130 are formed in one implantation process The P-type well region 390 has a first portion direct between the second well region 130 and the first well region 120 and a second portion direct between the third well region 160 and the second well region 130.

Based on the above discussions, it can be seen that the present disclosure offers advantages. It is understood, however, that other embodiments may offer additional advantages, and not all advantages are necessarily disclosed herein, and that no particular advantages are required for all embodiments. One advantage is that the drain region of the semiconductor device with different doping regions improves the discharging capability without performance degradation. The semiconductor device (e.g., MOSFET) may breakdown and discharge the pulse current stress at drain region where is far away from device surface and the gate structure. Further, low voltage drop and low surface electrical field can be achieved. Another advantage is that there is no additional mask and thus the manufacturing cost can be saved.

According to some embodiments, a semiconductor device includes a substrate, a first well region in the substrate, a gate structure over the substrate, a second well region and a third well region in the substrate and under the gate structure, and a source region and a drain region on opposite sides of the gate structure. The drain region is in the second well region and the source region is in the third well region. The drain region has a first doped region and a second doped region, and the first doped region and the second doped region have different conductivity types.

According to some embodiments, a semiconductor device includes a substrate, a first well region in the substrate, a gate structure over the substrate, a second well region and a third well region in the substrate and under the gate structure, and a source region and a drain region on opposite sides of the gate structure. The drain region is in the second well region and the source region is in the third well region. The drain region has a first doped region and a second doped region. The first doped region is between the gate structure and the second doped region. A depth of the second doped region of the drain region is greater than a depth of the first doped region of the drain region.

According to some embodiments, a method for manufacturing a semiconductor device includes forming a first well region and a second well region in a substrate. A third well region is formed in the second well region. A gate structure is formed over the second well region and the third well region, such that an interface of the second well region and the third well region extending downward from the gate structure. A first implantation process is performed with first dopants to form a source region in the third well region and a first doped region in the second well region. A second implantation process is performed with second dopants having a conductivity type different from the first dopants to form a second doped region such that a drain region including the first doped region and the second doped region is defined and the first doped region of the drain region is between the source region and the second doped region of the drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate;
a first well region in the substrate;
a gate structure over the substrate;
a second well region and a third well region in the substrate and under the gate structure; and
a source region and a drain region on opposite sides of the gate structure, the drain region is in the second well region and the source region is in the third well region, wherein the drain region has a first doped region and a second doped region, and the first doped region and the second doped region have different conductivity types.

2. The semiconductor device of claim 1, wherein the first doped region of the drain region is between the source region and the second doped region of the drain region.

3. The semiconductor device of claim 2, wherein the first doped region of the drain region and the source region have the same conductivity type.

4. The semiconductor device of claim 2, further comprising:
a bulk region adjacent to the source region, wherein the source region is between the bulk region and the drain region.

5. The semiconductor device of claim 4, wherein the second doped region of the drain region and the bulk region have the same conductivity type.

6. The semiconductor device of claim 1, wherein a dopant concentration of the second doped region of the drain region is in a range of 10¹⁸ atoms/cm³ and 10²¹ atoms/cm³.

7. The semiconductor device of claim 1, wherein a distance between the second doped region of the drain region and the gate structure is greater than a distance between the first doped region of the drain region and the gate structure.

8. The semiconductor device of claim 1, wherein a depth of the second doped region of the drain region is substantially the same as a depth of the first doped region of the drain region.

9. The semiconductor device of claim 1, further comprising:
a resist protective layer extending over a portion of the gate structure and over the drain region, wherein the resist protective layer is in contact with the first doped region of the drain region and spaced apart from the second doped region of the drain region.

10. The semiconductor device of claim 1, further comprising:
a heavily doped region below the second doped region of the drain region.

11. A semiconductor device comprising:
a substrate;
a first well region in the substrate;
a gate structure over the substrate;
a second well region and a third well region in the substrate and under the gate structure; and
a source region and a drain region on opposite sides of the gate structure, the drain region is in the second well region and the source region is in the third well region, wherein the drain region has a first doped region and a second doped region, the first doped region is between the gate structure and the second doped region, and a depth of the second doped region of the drain region is greater than a depth of the first doped region of the drain region.

12. The semiconductor device of claim 11, wherein the depth of the second doped region of the drain region is greater than a depth of the source region.

13. The semiconductor device of claim 11, further comprising:
a bulk region in the third well region and adjacent to the source region, wherein a depth of the bulk region is greater than the depth of the first doped region of the drain region.

14. The semiconductor device of claim 11, further comprising:
an isolation structure between the gate structure and the drain region.

15. A method for manufacturing a semiconductor device, comprising:
forming a first well region and a second well region in a substrate;
forming a third well region in the second well region;
forming a gate structure over the second well region and the third well region, such that an interface of the second well region and the third well region extends downward from the gate structure;
performing a first implantation process with first dopants to form a source region in the third well region and a first doped region in the second well region; and
performing a second implantation process with second dopants having a conductivity type different from the first dopants to form a second doped region such that a drain region including the first doped region and the second doped region is defined and the first doped region of the drain region is between the source region and the second doped region of the drain region.

16. The method of claim 15, wherein the second implantation process is performed after the first implantation process.

17. The method of claim 15, wherein performing the second implantation process further comprises forming a bulk region adjacent to the source region.

18. The method of claim 15, wherein the second implantation process is performed such that a depth of the second doped region of the drain region is greater than a depth of the first doped region of the drain region.

19. The method of claim 15, further comprising:
forming a spacer on a sidewall of the gate structure before performing the first implantation process.

20. The method of claim 15, further comprising:
forming a resist protective layer extending over a portion of the gate structure and over the third well region after performing the second implantation process.
